(19) United States
(12) Patent Application Publication
(10) Pub. No.: US 2011/0109855 A1
(43) Pub. Date: May 12, 2011

(54) POLYAMIC ACID AND A POLYIMIDE OBTAINED BY REACTING A DIANHYDRIDE AND A DIAMINE

(75) Inventors: Pinar KILICKIRAN, Stuttgart (DE); Zakir HUSSAIN, Stuttgart (DE); David DANNER, Stuttgart (DE); Akira MASUTANI, Stuttgart (DE); Gabriele NELLES, Stuttgart (DE); Shunichi SUWA, Tokyo (JP); Yuichi INOUE, Tokyo (JP); Shuichi SHIMA, Tokyo (JP)

(73) Assignee: SONY CORPORATION, Tokyo (JP)

(21) Appl. No.: 12/898,118

(22) Filed: Oct. 5, 2010

(30) Foreign Application Priority Data
Oct. 5, 2009 (EP) 09012588.1

(51) Int. Cl. G02F 1/1337; C08G 63/44; C08G 73/10; C08J 3/28; B32B 27/36; B32B 37/00; H05K 13/00

(52) U.S. Cl. 349/123; 528/229; 528/288; 525/435; 522/164; 428/336; 156/182; 29/592.1

(57) ABSTRACT

A polyamic acid and a polyimide obtained by reacting a dianhydride and diamines. A substrate having a film of such polyimide or polyamic acid deposited thereon. A liquid crystal display containing a film of such polyimide as an alignment layer. A method for reducing the response times of a liquid crystal display and/or for improving the on-state- and off-state-transmission and/or the voltage holding ratio of a liquid crystal display, the method involving incorporating the polyimide as an alignment layer in the liquid crystal display. A method of producing a liquid crystal display involving depositing a film of the polyimide on a substrate.

### CROSS-REFERENCE TO RELATED APPLICATIONS

The present application claims priority to European patent application EP 09012588.1, filed on Oct. 5, 2009.

### FIELD OF THE INVENTION

The present invention relates to a polyamic acid and a polyimide obtained by reacting a dianhydride and diamines. The invention also relates to a substrate having a film of such polyimide or polyamic acid deposited thereon. Moreover, the present invention relates to a liquid crystal display comprising a film of such polyimide as an alignment layer. Also, the present invention relates to the use of such polyimide and polyamic acid. Furthermore, the present invention relates to a method of producing a liquid crystal display.

### DISCUSSION OF THE BACKGROUND

Alignment of liquid-crystal (LC) materials is one of the most important issues in LCD fabrication. Generally polyimide (PI) films are used as alignment layers in LCDs because they have low dielectric constants and high thermal stabilities, they are inert to the liquid crystal materials and they provide stable LC alignments with high anchoring energies. Mainly rubbing the PI material has been employed for the alignment of the LC molecules. However, rubbing method has many disadvantages for LCDs such as 1) generation of debris and electrostatic charge which deteriorates the display quality and 2) dust. Therefore, rubbing-free methods to align LC molecules have been the focus of research in the recent years. Photo-alignment technique has the potential to replace the rubbing method since it overcomes the generation of electrostatic charge and dust by the rubbing process. There are three main ways to reach LC alignment by applying a photo-alignment process, 1) photoisomerisation, 2) photodimerization, 3) photodecomposition. The success of any one of these three methods depends very much on the polymeric material, namely the poylimide used [1-9]

The current display technologies require displays with high brightness and contrast, low power consumption, and very fast response times. Ways to improve the response speeds of LC materials can be classified into different groups. In the first one new, very fast LC mixtures need to be developed. In an other method additives such as inorganic micro or nano-particles, organic hydrogen-bond or complex forming materials, or organic bent core materials can be mixed to the existing liquid crystals. Finally, the PI materials which are used to align the liquid crystals can be designed and optimized such that besides providing an excellent contrast ratio by promoting very low off-sate transmission to the display, they can also give pre-tilt to the LC materials and by this way the response speeds can be improved.
1. J. van Haaren, Nature, 411, 29, 2001.
2. D. Chiou, L. Chen, Langmuir, 22, 9403, 2006.
3. W. M. Gibson, P. J. Shannon, S. T. Sun, B. J. Swetlin, Nature, 351, 49, 1991.
4. L. Chien, O. Yaroshcuk, U.S. Pat. No. 6,610,462 B2
5. N. Tamura, US patent, US 20070332780A1
6. M. Shadt, K. Schmidtt, V. Kozinkov, V. Chigrinov, J. J. of App. Phys. Part 1, 31, 2155, 1992.
7. M. Hasegawa, Y. Taira, International Display Research Conference, 94, 213, 1994.
8. S. ung, K. Cho, J. Park, Mat. Sci. and Eng. C, 24, 181, 2004.
9. Philip J. Martin, Recent Patents in Materials Science, 1, 21-28, 2008.
10. Buchnev O., Cheon C. I., Gluschenko A., Reznikov Yu., West J. L., 2005, Journal of the SID 13/9
11. Prechtl F., Haremza S., Parker R., Kuerschner K., Braun M., Hahn A., Fleischer R., 22 Jun. 2002, EP1213293
12. Meyer F., Schumacher P., Prechtl F., 27 Sep. 2000, EP1038941
13. Yasuda A., Bloor D., Cross G., Love G. Masutani A., 10 Jul. 2002, EP 1197791
14. Roberts. A, Masutani A., Yasuda A., Schueller B., Hashimoto S., Matsui E., 30 Jul. 2005, EP1541661
15. Kilickiran P., Masutani A., Roberts A., Tadeusiak A., Sandford G., Nelles G., Yasuda A., 3 Oct. 2007, EP1840188
16. Kilickiran P., Roberts A., Masutani A., Nelles G., Yasuda A., 3 Oct. 2007, EP1840188

Current electronic device display technologies require displays with high brightness and contrast, low power consumption and very fast response times. The liquid crystal materials known from the prior art and used in the displays do not fulfill the requirements of very fast turn-on- and turn-off-times, whilst at the same time keeping the contrast ratios, brightness and voltage holding ratios high. Accordingly, there is a need in the art for new materials that can be used in or as alignment layers to improve the alignment of the liquid crystal materials in order to obtain uniform brightness, a good contrast and fast response times

Liquid crystals are anisotropic in their optical, electrical and magnetic properties. It is the anisotropy of LC materials, which upon external forces such as boundary surfaces (the so-called alignment layers), electrical fields and magnetic fields give rise to different types of molecular orientations which is referred generally as LC alignment or orientation. A uniform alignment of LC materials on an oriented alignment layer is essential for high quality LC displays (LCDs). The out-of-plane tilt angle, as well as the in-plane orientation of LCs are very important factors. In optical configurations of LCDs, the pretilt angle which is given to the LC mixture by the alignment layer, is one of the most important parameters because it strongly influences the electro-optical properties of various LCD modes not only but including twisted nematic mode, supertwisted nematic mode, ferroelectric LC mode, vertically aligned mode, and in-plane switching mode.

Liquid crystal (LC) alignment properties in an LC display are mainly affected by the surface properties of alignment layers. In LCDs generally polyimide (PI) films are used as alignment layers. Rubbing these PI films by a velvet cloth or as such gives orientation to the LC materials, which is generally referred as alignment of LC materials. LC displays which are prepared by rubbed PI films generally suffer from two main disadvantages which are electrostatic charge that originates from rubbing and dust which comes from the material that is used for rubbing.

The polymers used as alignment materials directly affect the contrast of the displays because they play a very important role on the on- and off-state light transmission properties of LC materials. On the other hand, the alignment materials also have a very important role in the response properties of LC materials as well. An alignment material which can be designed and tuned to give a pre-tilt to the LC orientation will very likely improve the switching speeds of LC materials which is referred as the response speeds of LCs. The current display technologies require displays with high contrast, low power consumption, and very fast response times. With a suitable alignment layer the contrast of the displays can be improved because the LC orientation followed by the on- and off-state transmission properties will be improved. Also, if the alignment layer can be optimized to give a pre-tilt to the LC orientation than the results will be a LCD which requires less power to switch the LC materials and the LC materials will also switch faster because they will be pre-tilted.

### SUMMARY OF THE INVENTION

It was an objective of the present invention to provide new materials to be used in or to be deposited as alignment layers which will provide for good or even improved brightness, contrast and switching times. It was also an objective of the present invention to provide new materials that allow an improved uniform alignment of liquid crystal materials in liquid crystal displays. It was also an objective of the present invention to provide new materials to be used in alignment layers, which allow the provision of a pre-tilt to the liquid crystal material when in contact with such alignment layers. It was furthermore, an objective of the present invention to provide materials to be used in or as alignment layers which show high voltage holding ratios and good homeotropic alignment of liquid crystal material when in contact with these alignment materials.

### DETAILED DESCRIPTION OF THE INVENTION

In a first aspect, the present invention relates to a polyamic acid obtained by reacting a dianhydride, a first type of diamine and a second type of diamine, wherein said first type of diamine has a sidechain that is UV light dimerizable, said sidechain being selected from

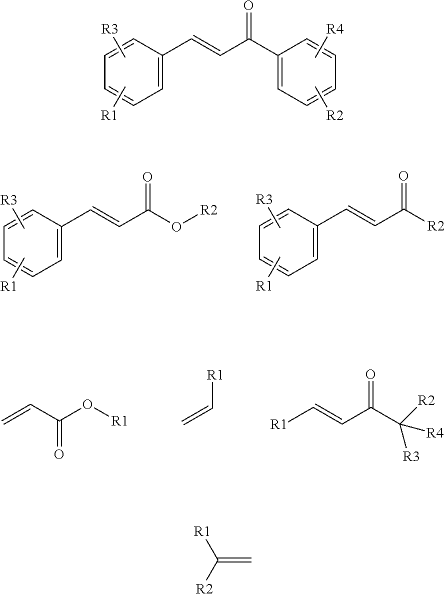

### Wherein

R1-R4 at each occurrence, are independently selected from the group comprising

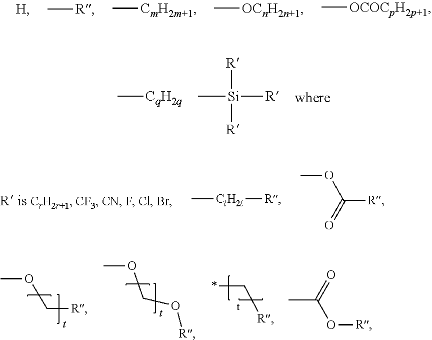

with the proviso that one of R1 to R4 is one of the aforementioned structures having R″, R″ denoting attachment of said sidechain to said diamine,
or wherein
(ii) R1 to R4, at each occurrence, are independently selected from the group comprising.

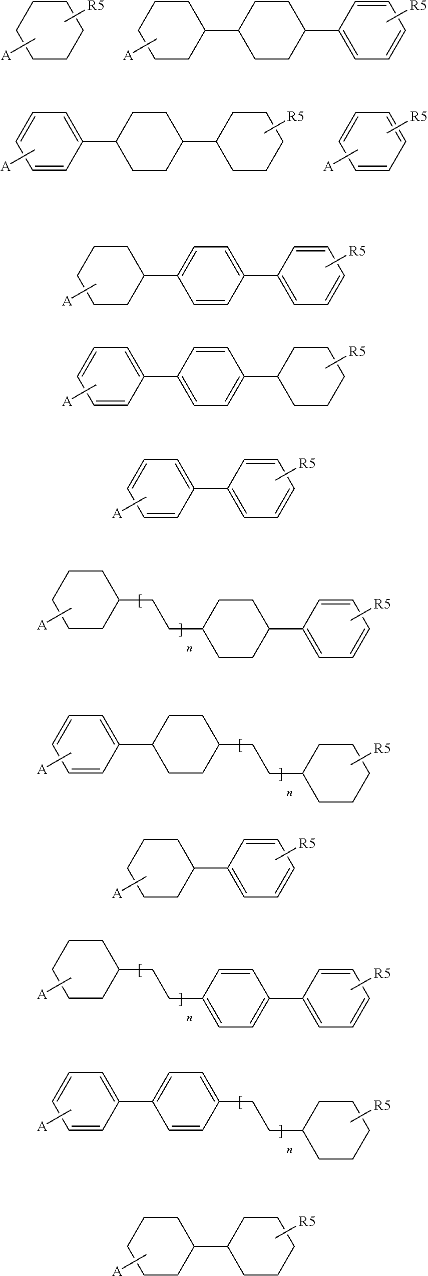

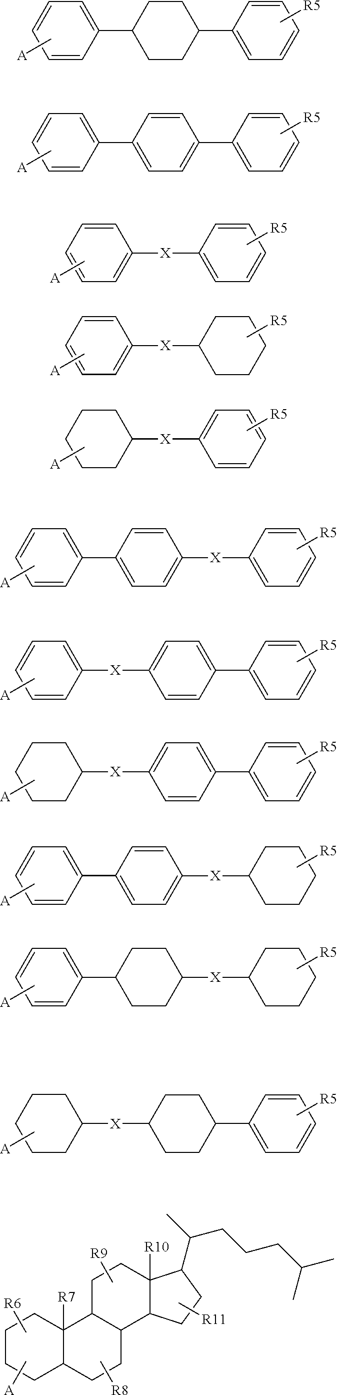

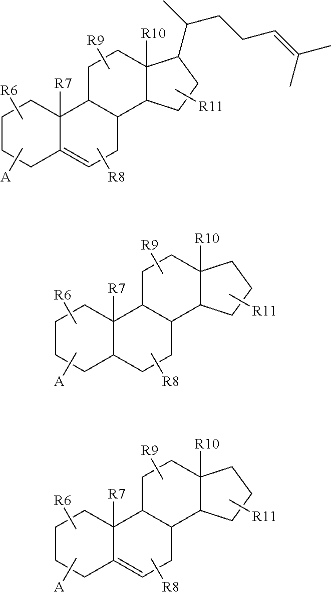

“A” representing the point of attachment at R1-R4; X being alkyl, ether, ester, cycloalkane, O, S, or NH; and wherein R5-R11 at each occurrence, are independently selected from the group comprising.

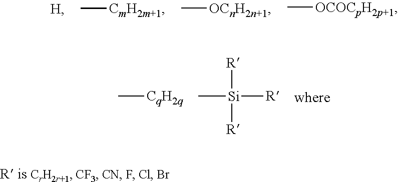

with the proviso that one of R1 to R4 is one of the aforementioned structures having R″, R″ denoting attachment of said sidechain to said diamine,
and wherein said second type of diamine has a sidechain
that promotes vertical alignment of a liquid crystal material, when in contact with said sidechain, said sidechain being selected from

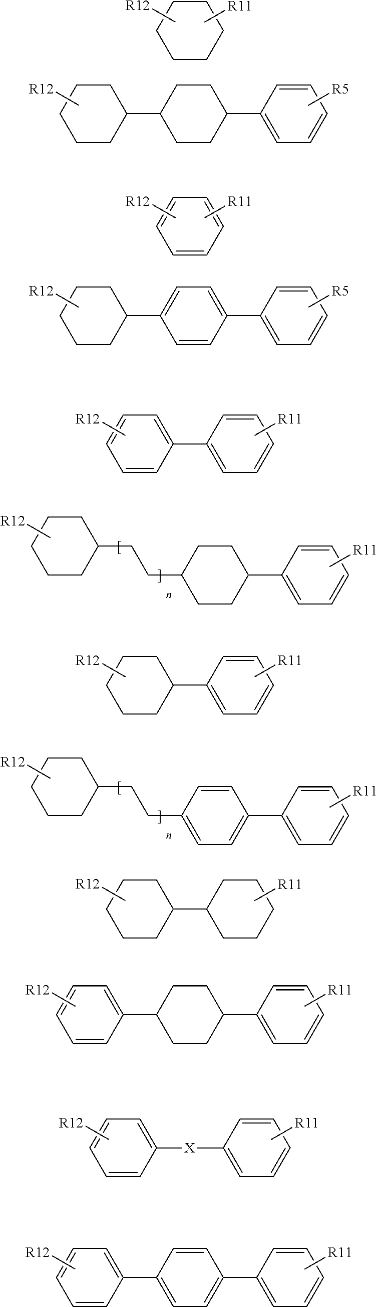

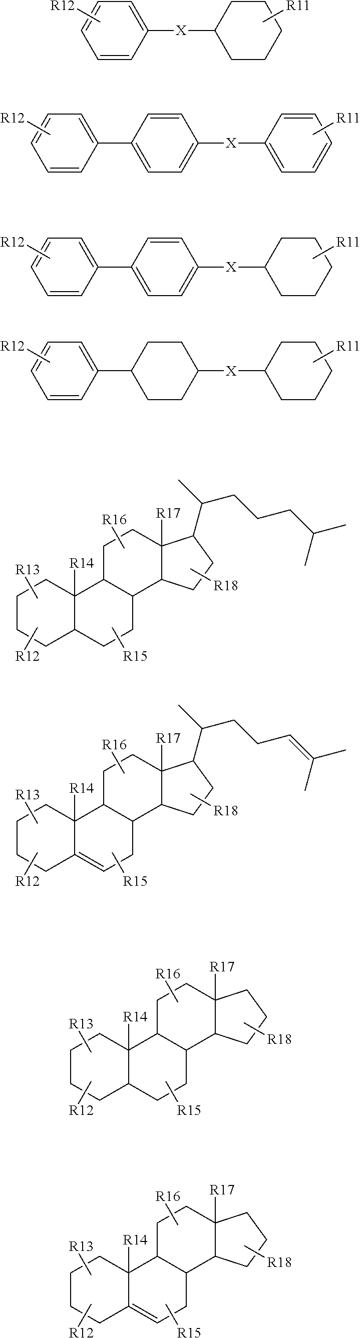

X being alkyl, ether, ester, cycloalkane, O, S, or NH; and wherein
(iii) R11-R18 at each occurrence, are independently selected from the group comprising.

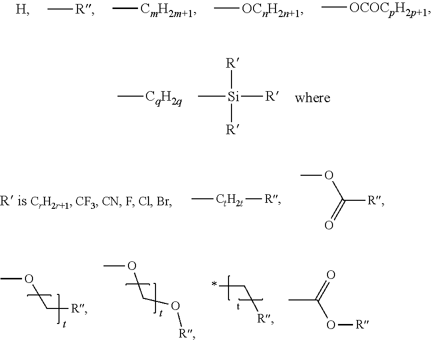

with the proviso that one of R11 to R12, is one of the aforementioned structures having R″, R″ denoting attachment of said sidechain to said diamine,
or wherein
(iv) R11 to R18 at each occurrence, are independently selected from the group comprising

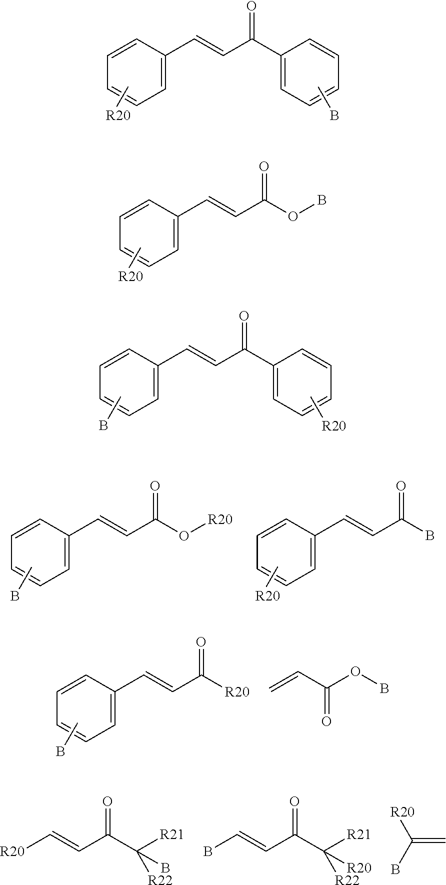

“B representing the point of attachment at R11-R18; and wherein R20-R22 are selected from the group comprising

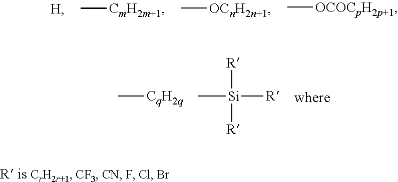

with the proviso that one of R11 to R12 is one of the aforementioned structures having R″, R″ denoting attachment of said sidechain to said diamine;
and wherein, in said polyamic acid, m, n, p, q, r, t are independently, at each occurrence, selected from 0 to 20, preferably 0 to 10, and
with the proviso that said polyamic acid has been obtained by reacting at least one type of diamine having a UV light dimerizable sidechain as defined above, and at least one type of diamine having a sidechain that promotes vertical alignment as defined above, with said dianhydride.

In one embodiment said dianhydride is selected from

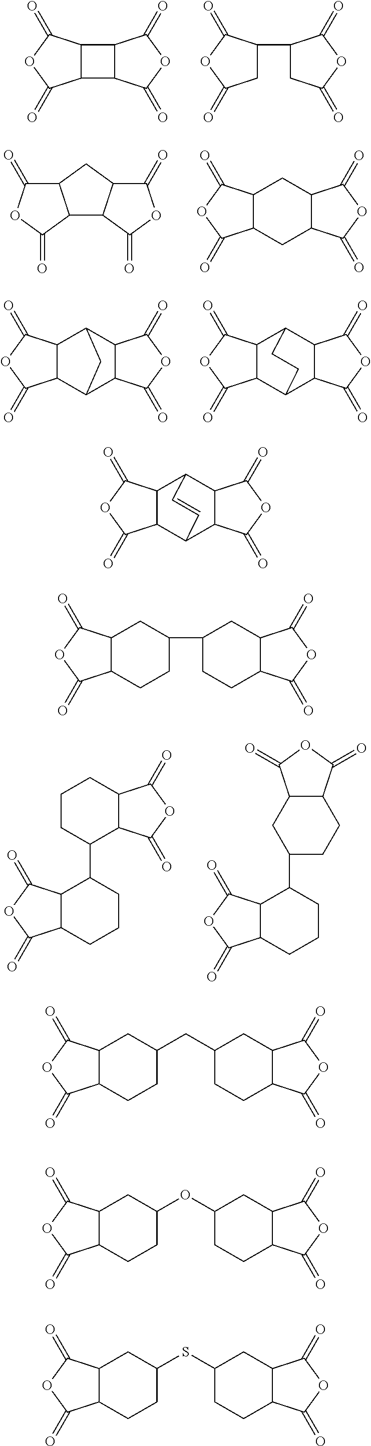

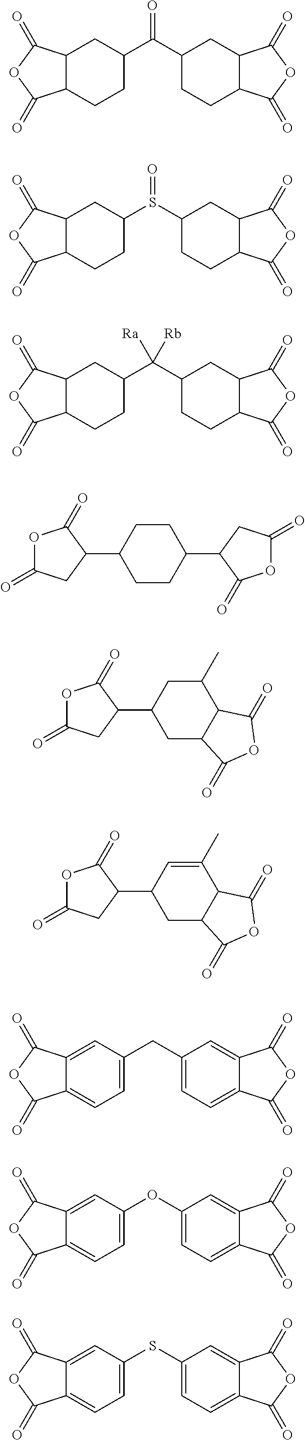

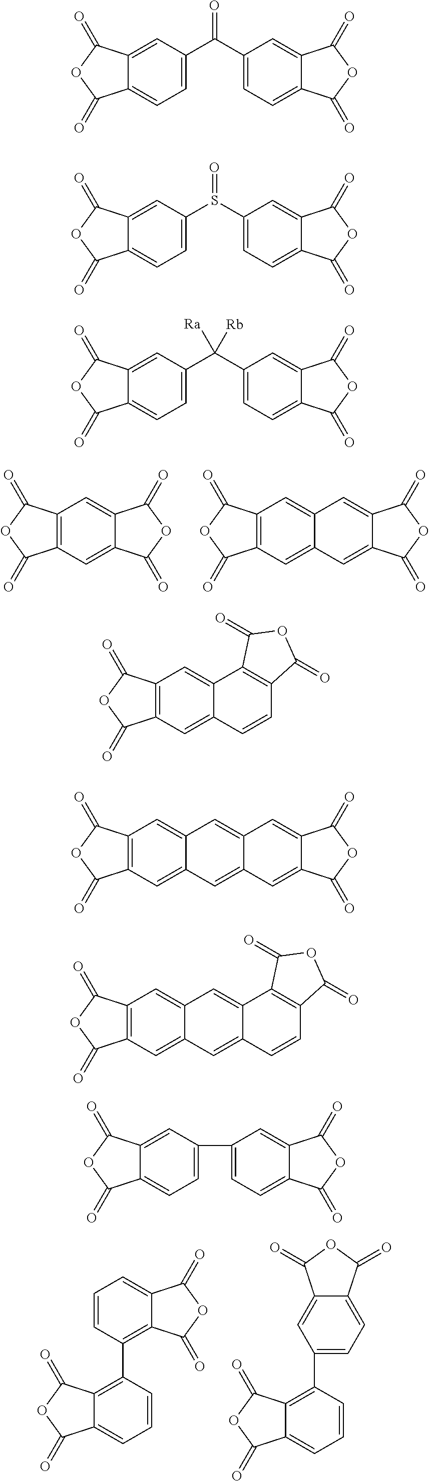

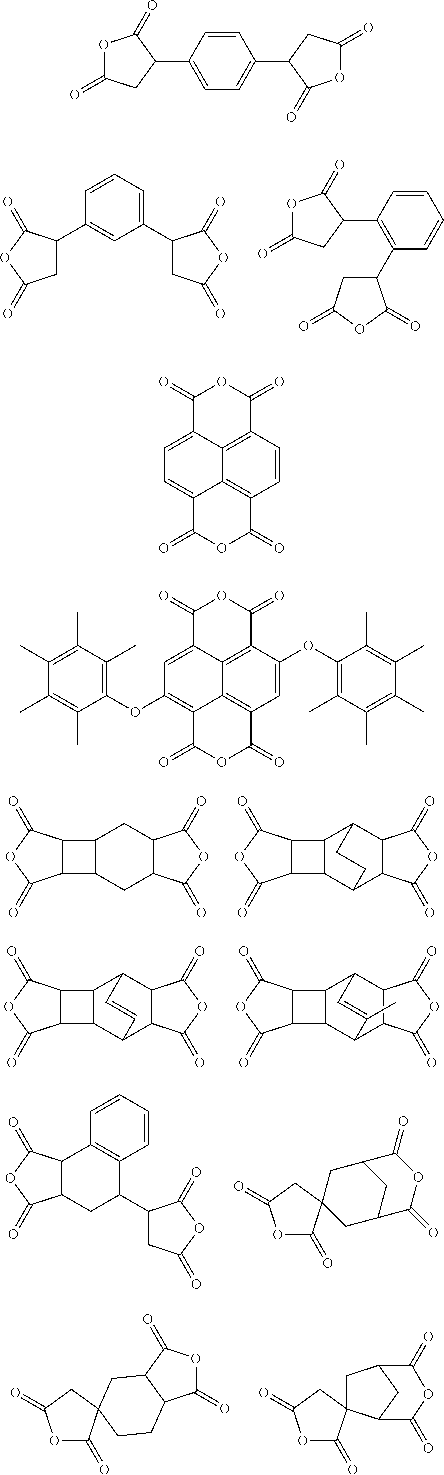

Ra and Rb being independently, at each occurrence, selected from alkyl, CF₃, F, Cl, Br, CN.

In one embodiment the diamine is selected from the structures:

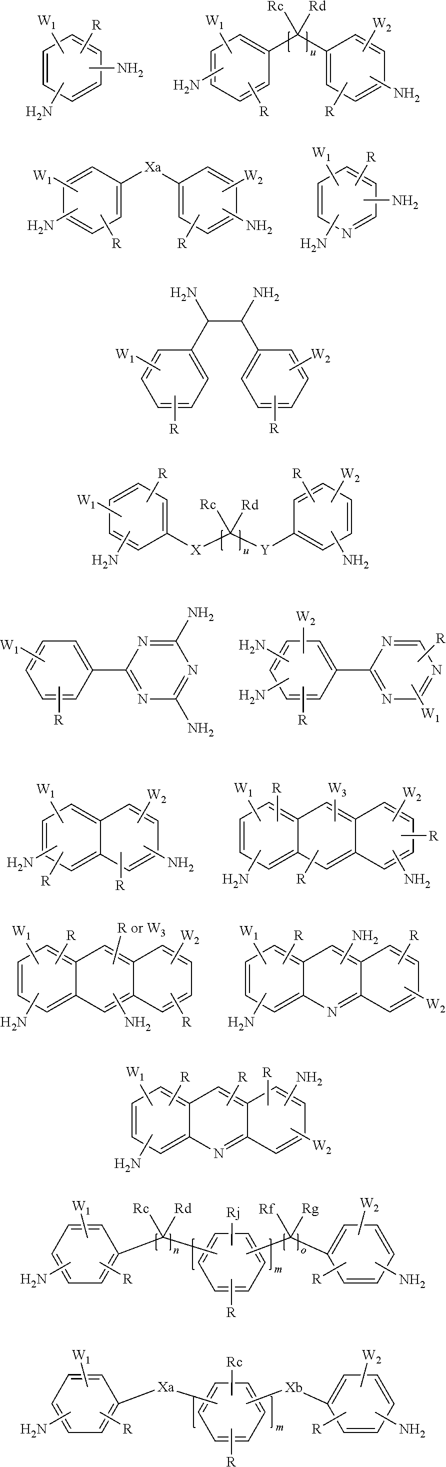

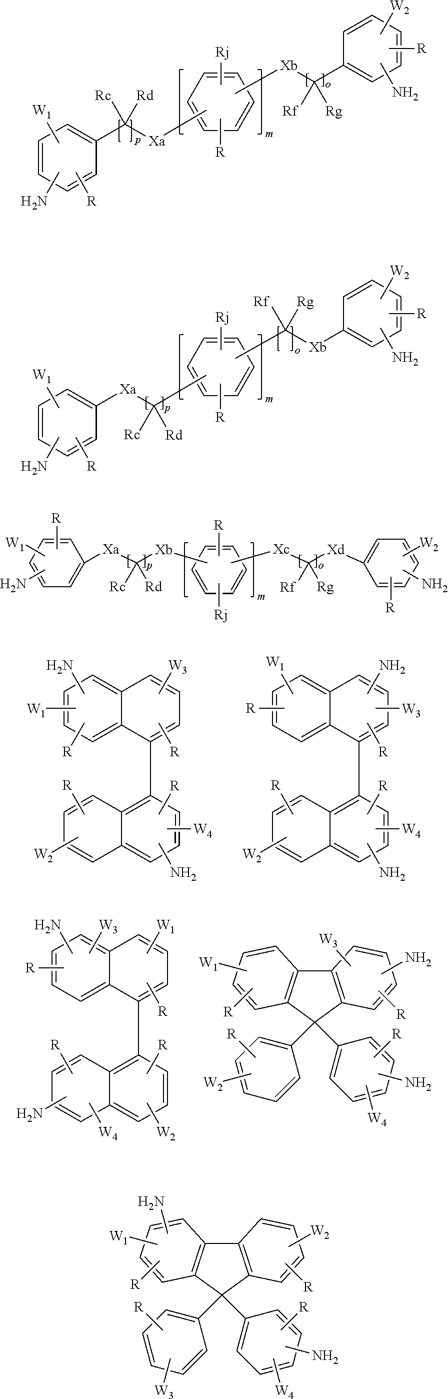

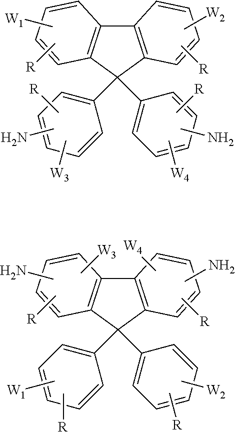

wherein
Rc, Rd, Rf, Rg, Rj are independently, at each occurrence, selected from; H, F, Br, Cl, CF₃, CN, CₙH_{2+‘}, OH, COORₑ where Rₑ=H or CₙH₂ₙ₊₁
Xa, Xb, Xc, Xd are independently, at each occurrence, selected from; CₙH₂ₙ, S, SO₂, N(Rₕ)₂ (Rₕ=H or CₙH₂ₙ₊₁), O, COO, CO
W₁ to W₄ are independently, at each occurrence, selected from; H, OH, CₙH₂ₙ₊₁, CF₃, Cl, Br, I, F, CN, COORₖ where Rₖ=H₂ₙ₊₁
n, m, o, p are independently, at each occurrence, selected from; 0 to 20
wherein R represents a sidechain as defined above.

In one embodiment the polyamic acid according to the present invention is obtained by additionally reacting said dianhydride with a third type of diamine, said diamine being as defined above, but having no sidechain as defined above, but instead having R═H.

The objects of the present invention are also solved by a polyimide obtained by reacting the polyamic acid according to the present invention with acetic anhydride, or exposing said polyamic acid to a temperature >100° C. for a period in the range of from 1 min to 24 h.

In one embodiment, the polyimide according to the present invention is selected from the structures

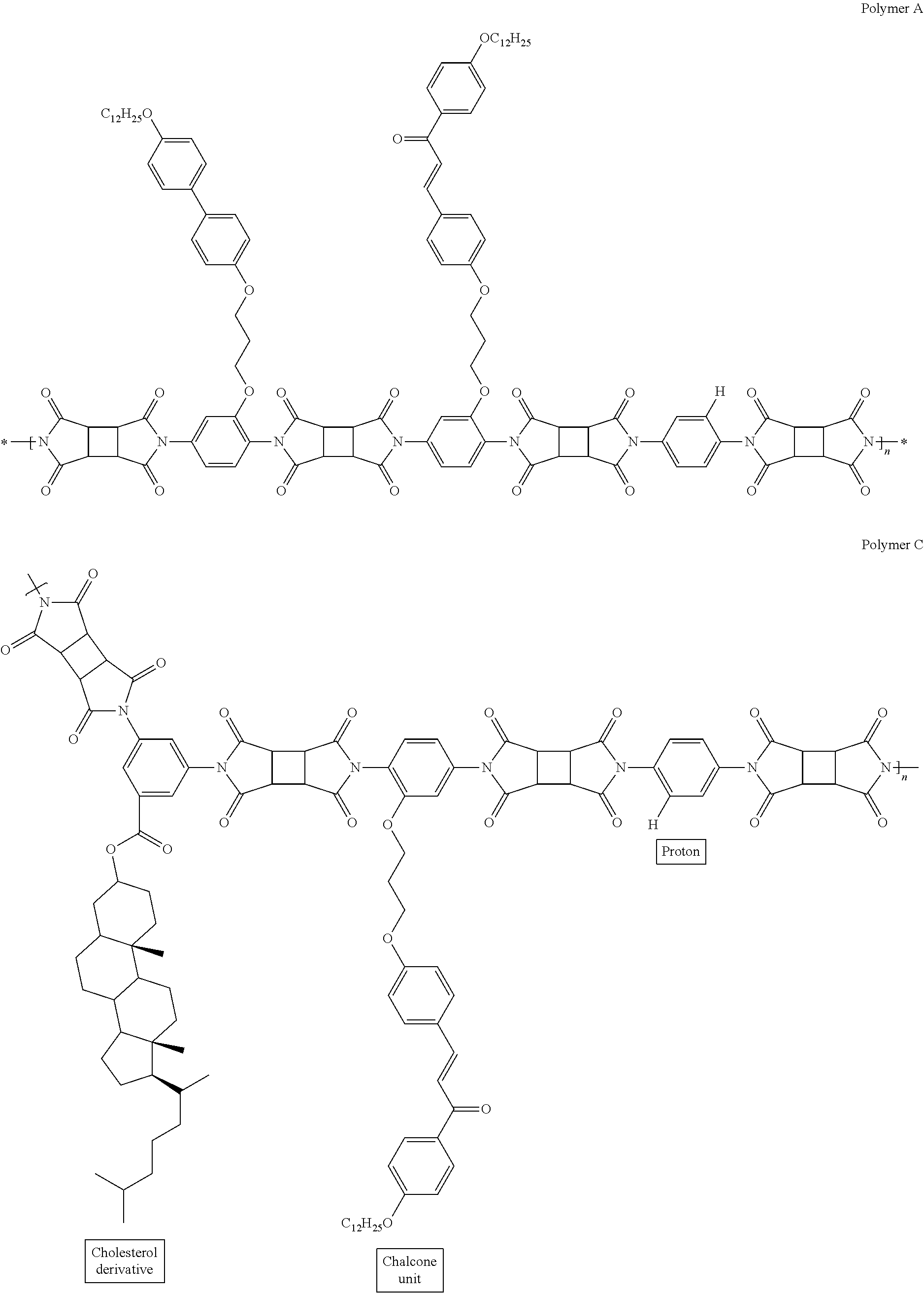

n being chosen such that the molecular weight of the polymer is in the range of from 20000 to 450000,
with the proviso that the arrangement of sidechains relative to each other within said polyimide is not limited to the one shown above.

In one embodiment after reacting said dianhydride and said diamines and after converting the resultant polyamic acid to a polyimide, the resultant polyimide is exposed to UV-radiation.

The objects of the present invention are also solved by a substrate having a film of polyimide, as defined above, deposited thereon, said film having a thickness in the range of from 50 nm to 2 μm, preferably from 50 nm to 1 μm, more preferably 50 nm to 500 nm.

The objects of the present invention are also solved by a liquid crystal display comprising an alignment layer for alignment of liquid crystal material within said liquid crystal display, said alignment layer being a film of polyimide, said polyimide being as defined above.

In one embodiment said film having a thickness in the range from 50 nm to 2 μm, preferably from 50 nm to 1 μm, more preferably from 50 nm to 500 nm.

In one embodiment, the liquid crystal display according to the present invention response times <40 ms at an applied voltage of 2.5 V, and <20 ms at an applied voltage in the range of from 3 V to 7.5 V, respectively, and/or a voltage holding ratio of >95%.

The objects of the present invention are also solved by the use of the polyimide according to the present invention, for reducing the response times of a liquid crystal display and/or for improving the on-state- and off-state-transmission and/or the voltage holding ratio of a liquid crystal display, said use comprising incorporating said polyimide as an alignment layer of said polyimide in said liquid crystal display.

The objects of the present invention are also solved by a method of producing a liquid crystal display comprising depositing a film of a polyimide, as defined above, on a substrate, contacting said film with a layer of liquid crystal material by applying said liquid crystal material to said film, providing a further substrate of said liquid crystal display and applying a further film of said polyimide as defined above thereon, contacting said layer of liquid crystal material with said further film of polyimide by applying said further substrate on said layer of liquid crystal material, thereby sandwiching the liquid crystal material between the two substrates.

The polyimides, in accordance with the present invention, have three properties which are provided by two different types of sidechains on the backbone: a) the polyimides have sidechains which provide for a homeotropic (i.e. vertical) alignment of the liquid crystal materials; b) the polyimides have sidechains which not only support the vertical alignment but also are UV-light dimerizable and therefore can provide pre-tilt to the liquid crystal materials; c) the sidechains also make the polyimides relatively soluble for further processing. Additionally, in the polymer backbone there may also be monomer units which do not have any sidechains but only hydrogen atoms. When these monomer units are present in the polymer backbone, then the sidechains are spaced apart to each other, and hence, further flexibility will be attributed to the polymeric system.

The term “UV light dimerizable”, as used herein in relation to sidechains, is meant to refer to a scenario in which the sidechains on the polymer are dimerized, preferably with the same or similar sidechains on the same polymer molecule or on another polymer molecule, thus leading to a dimer of two side chains on the same polymer molecule or a dimer of two polymer molecules.

The present invention also encompasses the polyamic acid molecules which are obtained in the afore-mentioned reactions between a dianhydride and a diamine. These polyamic acid molecules appear as intermediate products and, upon reaction with acetic anhydride or exposure to temperatures >100° C., react further to give the resultant polyimide. However, the present invention explicitly also claims the intermediate polyamic acid molecules. As described in the experimental part, upon addition of acetic anhydride to a reaction mixture which contains the polyamic acids in accordance with the present invention, these poylamic acid molecules are converted to the corresponding polyimide. Alternatively, when the reaction mixture containing the polyamic acid is spin coated on a display substrate and baked at oven at temperatures higher than 100° C., then again the conversion of polyamic acid molecules to polyimide occurs.

In one embodiment, the present invention also relates to a method of producing a polyamic acid in accordance with the present invention and a polyimide in accordance with the present invention, wherein a dianhydride, as defined above and diamines, as defined above, are reacted with each other, with the proviso that at least one type of diamine having a UV-light dimerizable sidechain, also as defined above, and at least one type of diamine having a sidechain that promotes vertical alignment, also as defined above, are reacted with said dianhydride.

The polyimides in accordance with the present invention can be used to produce alignment layers for use in liquid crystal displays. The alignment layers using these polyimides provide for excellent vertical alignment and, if UV-exposure is used, also a pre-tilt to the liquid crystal material. This alignment, in turn, provides for an excellent voltage holding ratio, good on- and off-state-transmission values as well as fast response times.

The polyimides in accordance with the present invention, when used in alignment layers, also provide for stronger contrast ratios and brightness of the resultant liquid crystal displays.

### BRIEF DESCRIPTION OF THE FIGURES

Moreover, reference is made to the enclosed figures, wherein

FIG. 1 shows an example of a reaction of a polyamic acid to give the resultant polyimide;

FIG. 2 shows an example of a polyimide formation starting with a dianhydride and a diamine via the intermediate polyamic acid;

FIG. 3 shows examples of dianhydrides in accordance with the present invention;

FIG. 4 shows possible substitution patterns of amino groups in the diamines in accordance with the present invention;

FIG. 5 shows a general formula for an ortho, meta and para-substituted diamine, taking benzene as an example;

FIG. 6 shows exemplary embodiments of diamines in accordance with the present invention; the diamines, R″, can be any of the structures shown in FIG. 6; the R-groups on these structures represent any of the sidechains shown in FIGS. 7a and 8a; there might be only one R-group (one sidechain) attached to one diamine molecule, or more than one R-group; e.g. groups may be attached to one, two, three or all aromatic rings present in the diamine, depending on the number of aromatic rings within the diamine.

FIG. 7a shows examples of sidechains which are UV-light dimerizable and provide a pre-tilt to liquid crystal material when in contact with the polyimides in accordance with the present invention having such sidechains incorporated in their structure; FIG. 7b shows possibilities for R1-R4 of FIG. 7a; FIG. 7c shows further possibilities for R1-R4 of FIG. 7a, and FIG. 7d shows possibilities for R5-R11 of FIG. 7c;

FIG. 8a shows examples of sidechains which promote vertical alignment (VA) in liquid crystal material, when in contact with polyimides in accordance with the present invention having incorporated such sidechains; FIG. 8b shows possibilities for R11-R18 of FIG. 8a; FIG. 8c shows further possibilities for R11-R18 of FIG. 8a; and FIG. 8d shows possibilities for R20-R22 of FIG. 8c;

FIG. 9 shows liquid crystal test displays which were coated with polyamic acid A (left panel), polyimide A (“polymer A”, middle panel), and another polyimide (“monomer B”, right-hand panel), using crossed polarizers (for an explanation of what “polyamic acid A”, “polyimide A” and “monomer B” mean, see further below);

FIG. 10 shows response speeds of a liquid crystal display panel using polymer A in an alignment layer on patterned ITO substrates; the liquid crystal display panels were subjected to UV-light and response time measurements before and after UV-irradiation were performed;

FIG. 11 shows polarized microscope pictures of on- and off-state of the liquid crystal material in a liquid crystal display panel using polymer A;

FIG. 12 shows polarized microscope pictures of vertical alignment using polyamic acid B (PAA-B) and polyimide B (“polymer B”) (PAA-B, PI-B);

FIG. 13 shows

a) the synthesis of “monomer A”;
b) the synthesis of “monomer B”;
c) the synthesis of polyimide A (“polymer A”);
d) the synthesis of “monomer D”;
e) the synthesis of polyimide B (“polymer B”); and
f) the synthesis of polyimide C (“polymer C”);

FIG. 14 shows

a) a polyimide only made from “monomer B” and a diamine with no sidechain attached (only hydrogens), as far as the diamines are concerned, plus a dianhydride;
b) the structure of polyimide A (“polymer A”) showing all the three different monomers that were used in the synthesis thereof, without the order of the sidechains (chalcone, biphenylene and hydrogen) being necessarily the one shown in the figure. Hence, the order may also be different;
c) the structure of polyimide B (“polymer B”) wherein a diamine without a sidechain and a diamine having a cholesterol based structure as its sidechain are reacted together with the dianhydride; it should be noted that, in polymer B, there is no UV dimerizable chain, and hence this polymer is not in accordance with the present invention;
d) the structure of polyimide C (“polymer C”), wherein three different diamines having different sidechains attached, namely a cholesterol based sidechain, a chalcone sidechain and no sidechain are reacted with a dianhydride; again, the order shown is not necessarily the order in which the sidechains appear in the resulting polymer;
e) the synthesis of polymer A using three different diamines with different sidechains;
f) the synthesis of polymer C using three different diamines with different sidechains.

Moreover, reference is made to the examples which are given to illustrate, not to limit the present invention.

### EXAMPLES

### Example 1

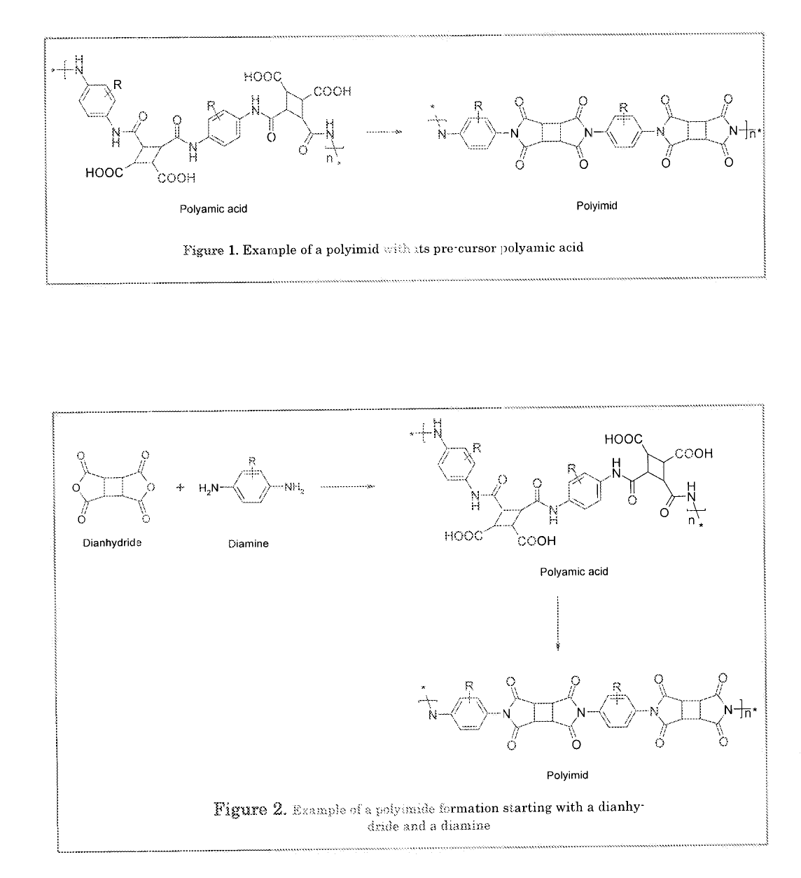

A polymer backbone which can be referred as polymer main chain is a polyimide or a polyamic acid material. Polyamic acids are the pre-cursor materials of polyimides as shown in a simple example in FIG. 1.

The polyimide material or its pre-cursors polyamic acid material is prepared from a reaction between a dianhydride and a diamine. A general example of the formation of a polyimide starting from a dianhydride and a diamine is given in FIG. 2.

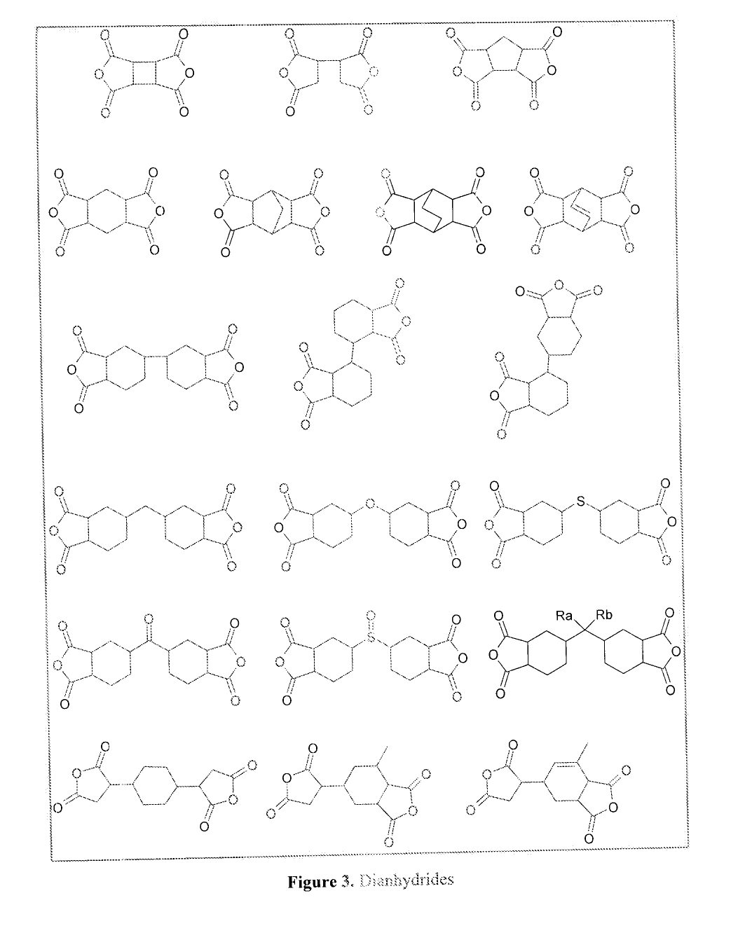

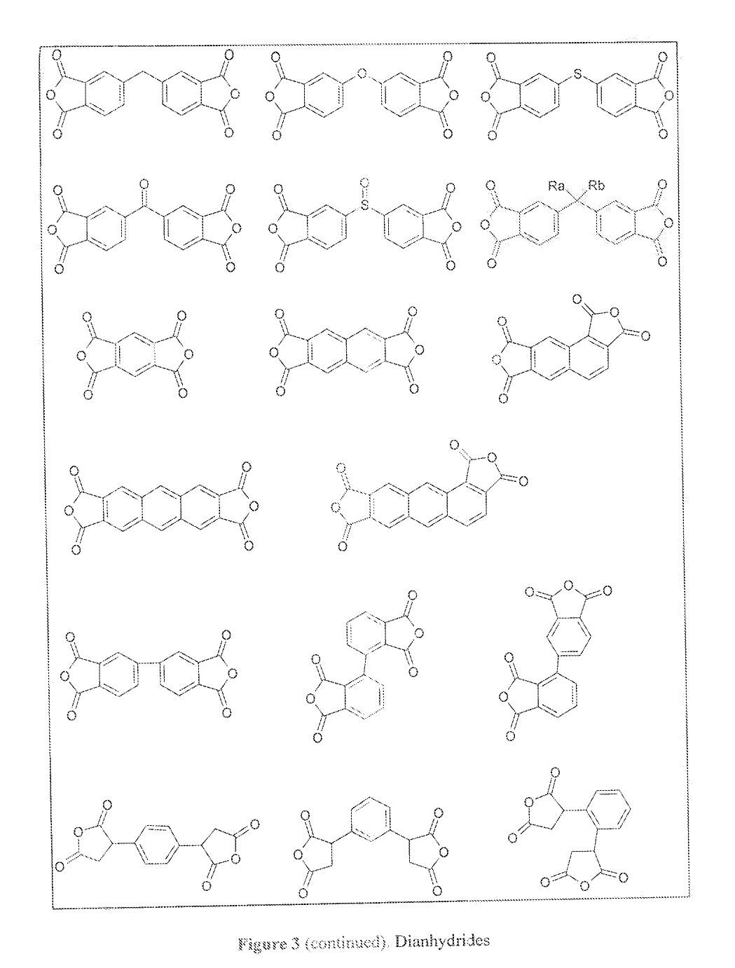

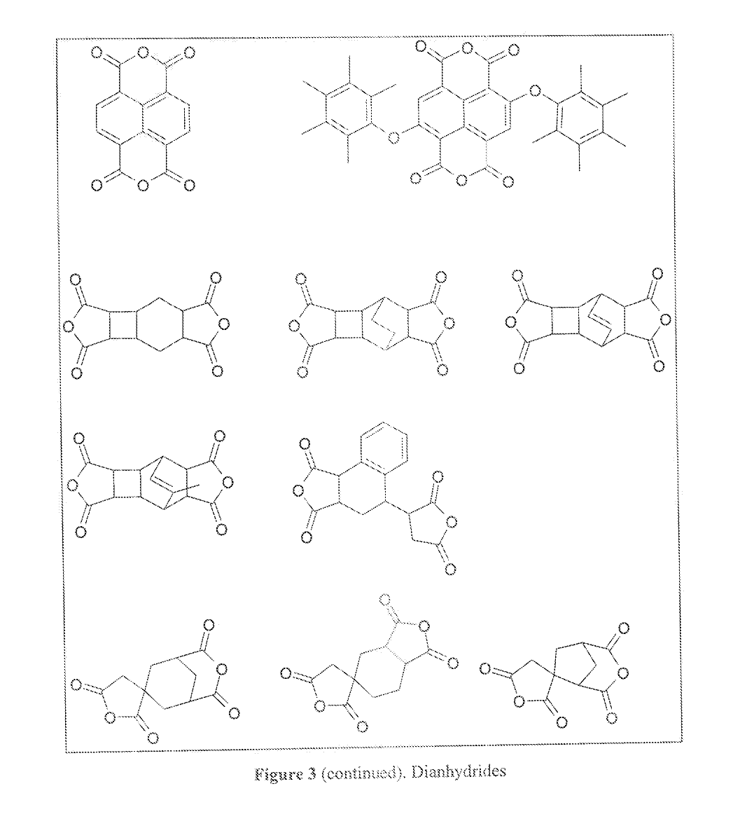

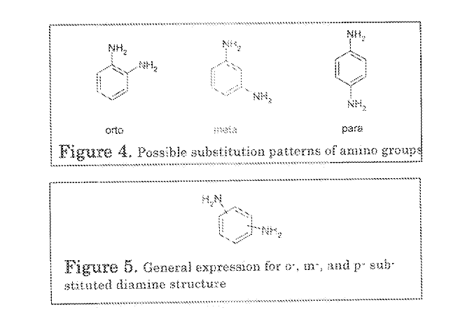

The dianhydride which is used to synthesize the claimed polymers is not limited but preferably selected from the materials whose structures are given in FIG. 3 (please see attachment).

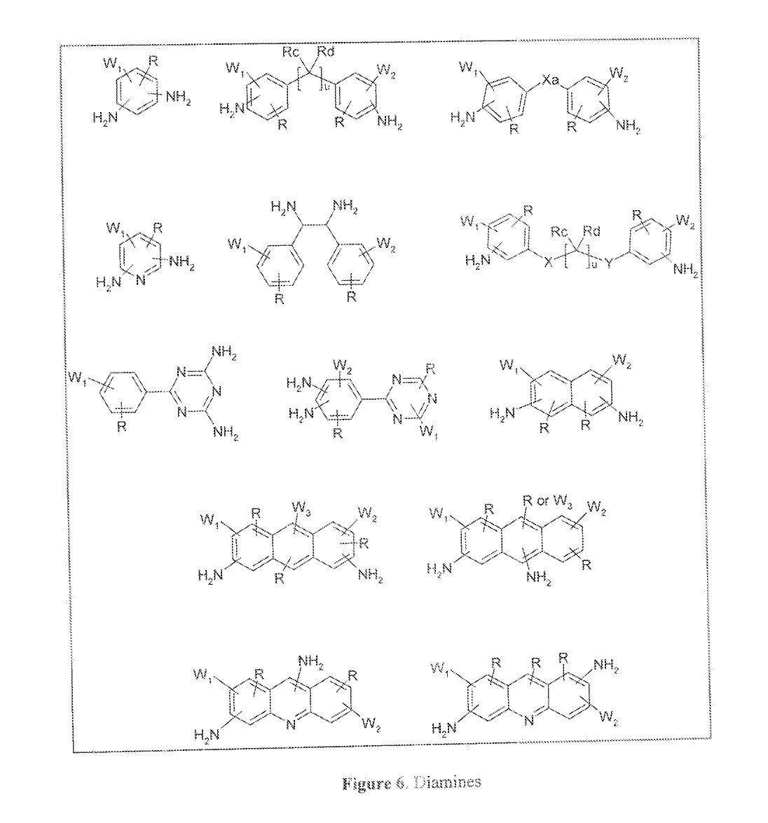

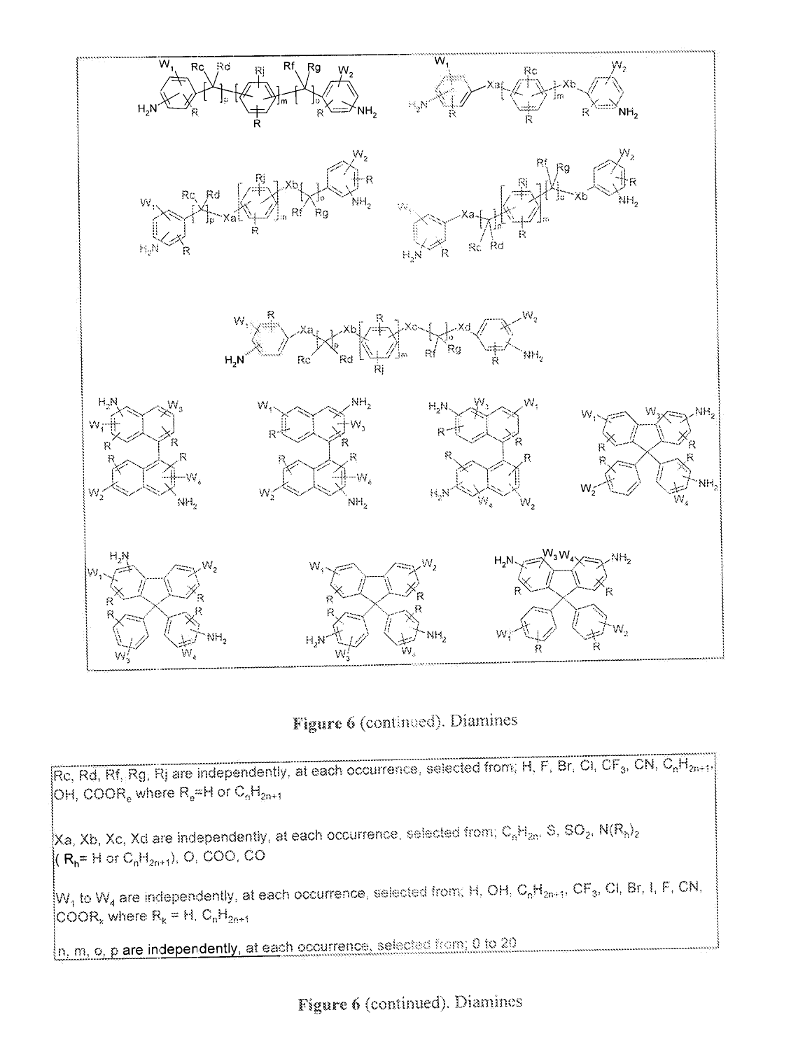

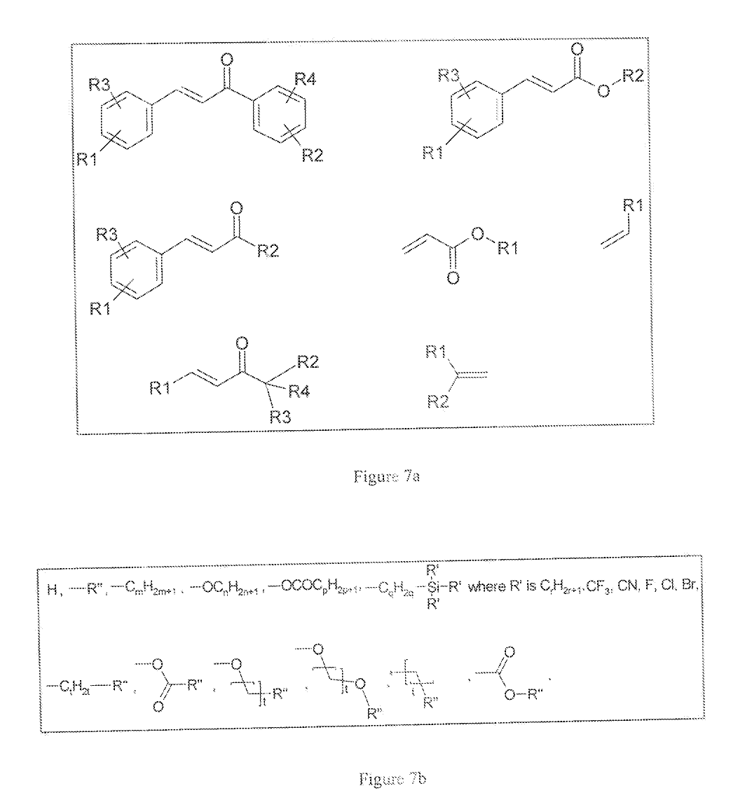

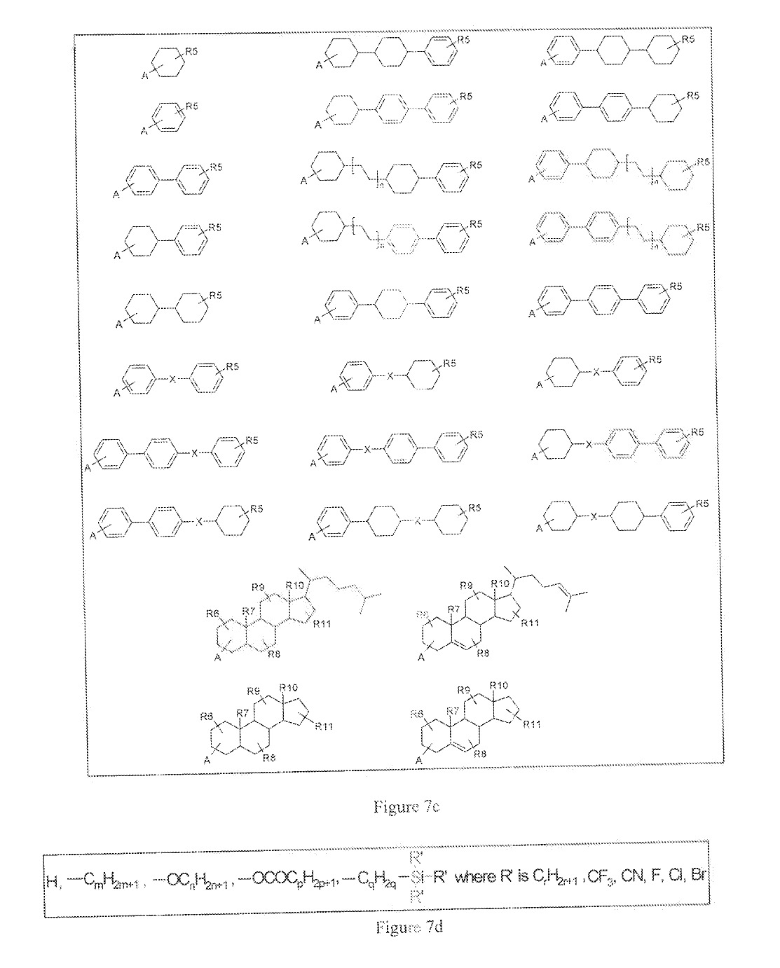

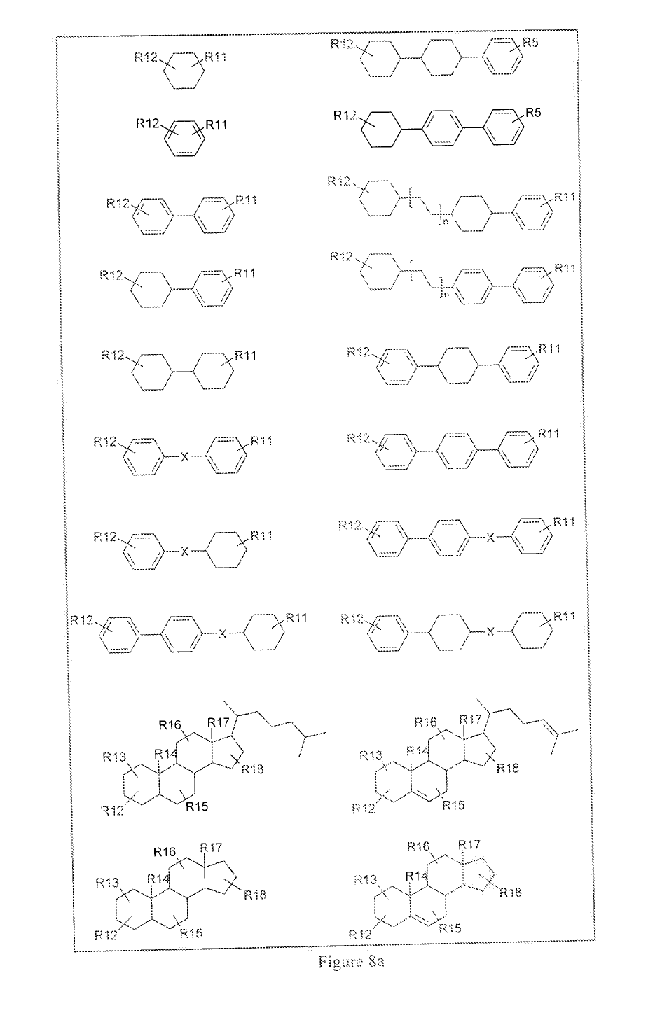

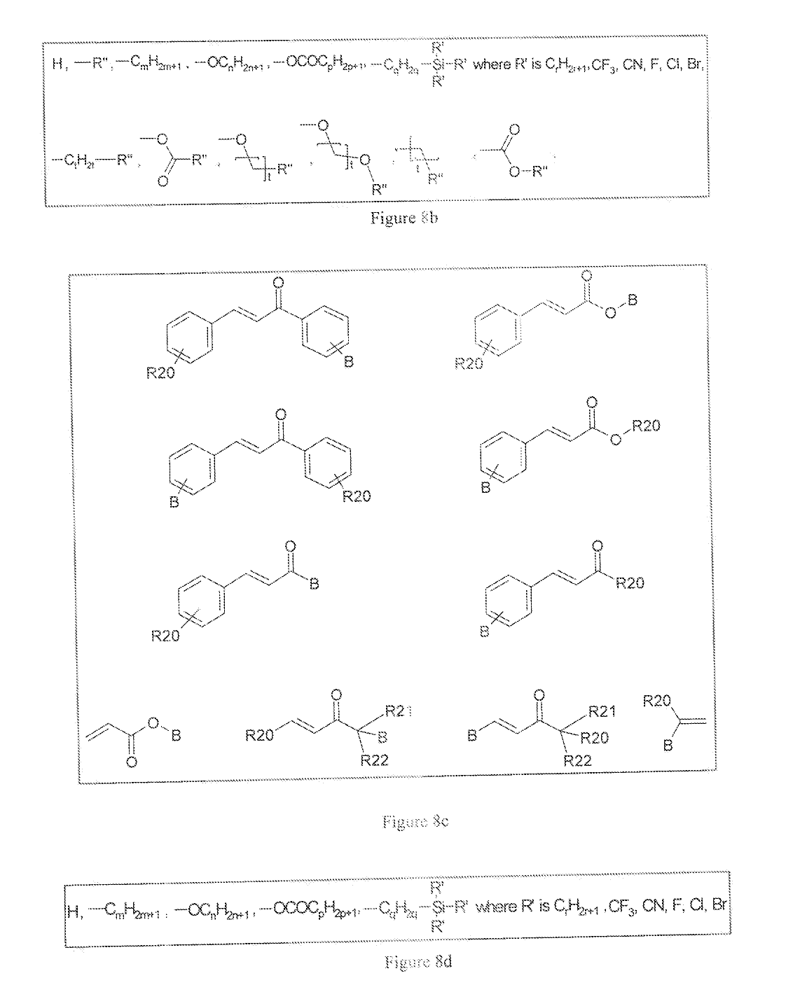

The diamino groups of diamines can be attached to a benzene ring in any of the three patterns, namely, ortho (O), meta (in), or para (p) as shown in FIG. 4. We show these substitution patterns in a general structure as provided in FIG. 5, without wishing to be limited to a benzene ring. Instead of the benzene ring any other aromatic ring structure can be envisaged having the general substitution pattern of FIG. 5. The diamine which is used to synthesize the claimed polymers is not limited but preferably selected from the materials whose structures are given in FIG. 6. In FIGS. 7 & 8, the diamines are designated as R″.

The structures claimed in FIG. 7a have the capacity to dimerize under UV light, so these structures are claimed to be necessary not only for the good vertical alignment but also necessary to give pre-tilt to the liquid crystals.

The structures shown in FIG. 8a are claimed to be necessary to have a good vertical alignment due to their rigid and bulky structures.

The structures shown on both FIGS. 7a and 8a represent the R groups on the polyimide materials whose general structure is shown in FIG. 2.

### Example 2

### Synthesis

### 1. Synthesis of Monomer A

A complete scheme for the synthesis of monomer A is shown in FIG. 13a).

In the first reaction amino nitro phenol 1 (6.5 mmol) was coupled with dibromo propane 2 (6.5 mmol) in the presence of potassium carbonate (10.0 mmol) by refluxing in acetone (40 mL) for 24 h. After completion of the reaction, potassium carbonate was removed by filtration and the solvent was evaporated to get the crude product. Final purification was carried out through a column of silica gel by eluting with pentane/ether (6:4) to yield amino nitro ether 3 in ˜80% yield.

Following the synthesis, amino nitro ether 3 (3.0 mmol) was subjected to further etherification reaction with 4-hydroxy benzaldehye 4 (3.0 mmol) in the presence of potassium carbonate (6.0 mmol) in refluxing acetone (50 mL) for 24 h. After completion of the reaction (TLC confirmation), potassium carbonate was filtered and the solvent was evaporated under reduced pressure to get crude product. Final purification was carried out through a column of silica gel with ether/pentane (6:4 to pure ether)) as solvents to afford aldehyde ether 5 as a yellow solid in 75% yield. NMR data confirmed the structure of aldehyde with strong aldehyde proton as well as NH2 protons signals in addition to all other relevant protons.

Continuing the synthesis, above aldehyde 5 (6.0 mmol) was coupled with substituted acetophenone 6 (6.0 mmol) in the presence of methanol (40 mL) and sodium methoxide solution (10 mL, 20%). The mixture was stirred at r.t. for 24 h and then it was added with 2N HCl and water and extracted two times with dichloromethane. Combined organic layers were dried with magnesium sulfate, filtered and evaporated to yield the crude product. Final purification was carried out by column chromatography with ether/pentane (3:7 to pure ether) as solvents. Synthesis of amino nitro chalcone 7 through this reaction (Claisen-Schmidt condensation) resulted in yellow solid in ˜60% yield. Structure of the chalcone 7 was again confirmed through its NMR data that indicated the presence of olefinic protons signals in addition to all other relevant signals.

Final step for the synthesis of monomer A was the reduction of NO2 to NH2. In this case, a mixture of amino nitro intermediate 7 (1.0 mmol), SnCl2 (4.0 mmol) and 20 mL of ethanol was stirred while 4.0 mL of conc. HCl was added slowly. After addition of HCl was over, the mixture was refluxed for 1 h. Excess ethanol was evaporated and the remaining solution was poured into 50 mL of distilled water. The solution was basified with 10% NaOH solution, extracted with ether and the organic layer was dried, evaporated to get the yellow solid. Due to its instability (turned darker after keeping in fridge), it was either chromatographed with silica gel column chromatography or recrystallized on the same day to afford final diamine monomer 8 in ˜80% yield. In some cases, after completion of reaction, reaction contents were poured into water and basified with 10% NaOH solution and the precipitate formed were isolated, washed with hot water and cold methanol, dried and chromatographed to get light yellowish solid. Final monomer A (8) was again characterized by its NMR data indicating the protons signals due to NH2 in addition to aliphatic, olefinic and aromatic protons.

### 2. Synthesis of Monomer B

The synthetic scheme describing the synthesis of monomer B is shown in FIG. 13 b):

Selective coupling of dihydroxy biphenyl 9 (2.6 mmol) was carried out with the already synthesized amino nitro ether 3 (2.6 mmol) in the presence of potassium carbonate (4.0 mmol) in refluxing acetone (20 mL). After refluxing the mixture for 24 h, TLC indicated the formation of ether in addition to un-reacted dihydroxy biphenyl. Mixture was cooled to r.t. and solvent was evaporated to yield the crude product as white solid. It was further purified through column chromatography with pentane/ether (7:3) as solvents. Reaction worked well and phenol intermediate 10 was isolated as yellow solid in good yield (˜65%). This intermediate was characterized by its NMR data where in addition to all other signals; signals due to biphenyl could be seen clearly.

Following the synthesis, etherification of intermediate phenol 10 (1.0 mmol) was carried out in the presence of dodecyl bromide (1.0 mmol) in potassium carbonate (2.0 mmol) in refluxing acetone (20 mL). Mixture was refluxed for 24 h, cooled to r.t. and solvent was evaporated to yield the crude product as yellow solid. It was further purified through column chromatography with pentane/ether (1:1) as solvents. In this case, reaction worked as well and intermediate ether 11 was isolated in good yield (˜60%). This intermediate was again characterized through its NMR data.

Final step for the synthesis of monomer B (12) was the reduction of NO2 group to NH2. Therefore, a mixture of amino nitro intermediate 11 (0.5 mmol), SnCl2 (2.0 mmol) and 10 mL of ethanol was stirred while 2.0 mL of conc. HCl was added slowly. After addition of HCl was over, the mixture was refluxed for 1 h. Excess ethanol was evaporated and the remaining solution was poured into 50 mL of distilled water. The solution was basified with 10% NaOH solution, extracted with ether and the organic layer was dried, evaporated to get the yellow solid. It was immediately purified by silica gel column chromatography with dichloromethane/acetone as solvents. In some cases, after completion of the reaction, contents were poured into water and basified with 10% NaOH solution and the precipitate formed were isolated, washed with hot water and cold methanol, dried and chromatographed to get light yellowish solid. Yield in most of the cases was ˜65% of the isolated diamine 12. Monomer B was again characterized through its NMR data.

### 3. Synthesis of Polyimide (Polymer A) (Monomers A/B/C; 25/50/25)

The synthetic route for the polyimide A (polymer A) synthesis is shown in FIG. 13 c).

In a typical procedure, diamines 8, 12, 13 (25/50/25%, 1.53 mmol) were dissolved in N,N-dimethylformamide (˜20 mL) and dianhydride 14 (1.53 mmol) was added to the solution. The reaction flask was evacuated and filled with dried nitrogen three times. The reaction mixture was stirred at room temperature for 24 h leading to the formation of polyamic acid. To this polyamic acid containing mixture, a mixture of acetic anhydride (0.1 mL) and pyridine (0.1 mL) was added. Stirring of the mixture was continued at 80 degree C. for 3 h and the resulting solution was poured into methanol and white precipitate (turned light brownish after complete addition) was collected by filtration. Polyimide 15 was obtained as light brownish powder after being dried in a vacuum oven at room temp. for 6 hours.

Polymer formed was again characterized through its NMR data as well as FTIR, DSC and GPC analysis. In NMR, some representative signals could be seen. FT-IR indicated the presence of imide carbonyl signals. Molecular weight of the polymer formed was 88600 which was found through GPC data. It is important to note that the range of molecular weights of polymer synthesized, in other experiments, was 20,000 to 120,000. On the other hand, when a polyamic acid is first spin coated and then converted by baking at temperatures >100° C., e.g. in an oven to polyimide then the polymers' molecular weight may go even higher. The molecular weights of the polyimides may be in the range of from 20,000 to 450,000.

### 4. Synthesis of Monomer D (19)

The scheme for the synthesis of cholesterol based monomer D (19) is shown in FIG. 13 d). In this case, dinitro benzoic acid chloride was reacted with cholesterol in the presence of base (Et3N) where 5α-cholestan-3β-ol 16 (10 mmol) was dissolved in a mixture of dry triethylamine (5 ml) and dry chloroform (50 ml). The flask was immersed into an ice bath and 3,5-dinitobenzoic acid chloride 17 (20 mmol; excess) was added. Mixture was stirred for 8 h at room temperature under nitrogen atmosphere, followed by stirring at 60° C. for 2.5 h. The reaction mixture was cooled to r.t., poured into water and extracted with chloroform. Combined organic layers were dried and solvent was evaporated to afford crude product. For initial purification, crude product was recrystallized from acetone twice. Final purification of semi pure ester 18 was carried out through filtering over a short pad of silica by using dichloromethane as solvent to obtain slightly yellow solid in 85% yield. Structure of the newly synthesized ester 18 was confirmed through its NMR analysis.

Final step in the synthesis of monomer D (19) was the reduction of nitro groups to amino groups. In this case, conc. hydrochloric acid (5 ml) was added to a mixture of 3,5-dinitrobenzoic acid cholestanyl ester 18 (2 mmol) and anhydrous SnCl₂ (10 mmol) in ethanol (50 ml). The mixture was refluxed for 4 h. After cooling it to r.t., mixture was poured into water and basified with 10% NaOH. Mixture was extracted with dichloromethane and the organic layer was washed with water and dried over magnesium sulfate. After removing the solvent under reduced pressure, crude product was obtained which was purified by silica gel column with dichloromethane/acetone (1:1) as solvents to afford final diamine 19 in 75% yield. Structure of the final monomer D (19) was again confirmed through its NMR data.

### 5. Synthesis of Polyimide B (Polymer B) (monomers D/C; 50/50)

The synthetic scheme describing synthesis of polyimide B (“polymer B”) is shown in FIG. 13 e).

Monomer D, 3,5-diaminobenzoic acid cholestanyl ester 19 (0.288 mmol), monomer C, 1,4-phenylenediamine 13 (0.288 mmol) and dianhydride, 1,2,3,4-cyclobutanecarboxylicdianhydride 14 (0.576 mmol) were stirred in anhydrous DMF at room temperature under nitrogen atmosphere for 16 h leading to the formation of polyamic acid. To this polyamic acid containing mixture, a mixture of pyridine and acetic anhydride was added and the mixture was stirred at 80° C. for 2.5 h. 200 mg of slightly yellow-brownish product, poorly soluble in DMF, was received after recrystallizing in MeOH and drying in vacuo. Structure of the final polyimide 20 was confirmed through its NMR analysis.

### 6. Synthesis of Polyimide C (Polymer C) (Monomers A/D/C; 25/50/25)

The synthetic scheme describing synthesis of polyimide C (“polymer C”) is shown in FIG. 13 f).

Monomer A 8 (172 mg; 0.3 mmol), monomer D 19 (314 mg; 0.6 mmol), monomer C, 1,4-phenylenediamine 13 (32 mg; 0.3 mmol) and dianhydride, 1,2,3,4-cyclobutanecarboxylicdianhydride 14 (235 mg; 1.2 mmol) were stirred in anhydrous DMF at room temperature under nitrogen atmosphere for 15 h leading to the formation of polyamic acid. To this polyamic acid containing mixture, a mixture of 100 μl pyridine and 200 μl acetic anhydride was added and the mixture was stirred at 80° C. for 2.5 h. 550 mg of yellow-brownish product was received after recrystallizing in MeOH and drying in vacuo. Structure of the copolymer 21 was again confirmed through its NMR analysis.

### Example 3

### Test Displays Prepared Using the Polyamic Acids and the Corresponding Polyimides

A typical procedure to prepare a test display panel using a newly synthesized polymeric material is as such: In a lithography room, both glass substrates of the display panel are covered with 3% (w/w) polymer solution in NMP (N-methyl-2-pyrrolidon). Or, they are covered with a fresh polyamic acid solution which is directly taken from the reaction mixture (please refer to the synthesis part for the reaction solution/mixture of a polyamic acid). The materials are then spin coated at 200Rps for 10 s, 600Rps for 5 s, 2000Rps for 10 s and 4000Rps for 1 s. The spin coated substrates are then placed in an oven filled with nitrogen (Heraeus thermicon P) and are pre-baked for 3 min at 80° C. and baked for 60 min at 200° C. After the substrates are cooled down to room temperature they are used to sandwich the negative type liquid crystal with spacers (0.5% of 5 μm Hayabead polymer spacer from Hayakawa). Finally, the liquid crystal cell is annealed for 30 min at 80° C. on the hot stage. The thickness of the film is measured with profilometer and it is in the range of 120-150 nm.

The figures (FIG. 9) of polyamic acid, polyimid (PI, polymer A) and polyimid (monomer B) coated test display panels were taken using crossed polarizers, on a Na-lamp table. From the pictures it is clearly seen that both PAA and PI have provided vertical alignment to the negative type LC used. Whereas, if the polyimid made of only monomer B is used then it was not possible to achieve the vertical alignment. This example shows the effectiveness of using two side chains on one polymer to achieve a VA even if one of the side chains do not promote this alone.

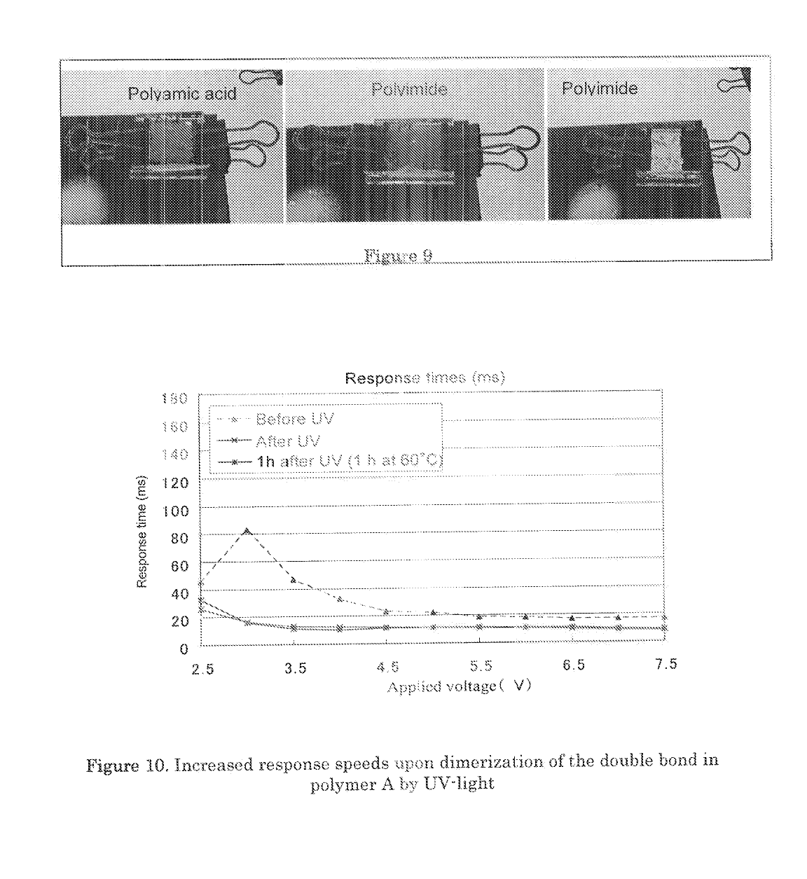

In another experiment, the display test panels are prepared using patterned ITO substrates which are coated with polymer A. In this test panel again a negative type liquid crystal was used. The test panels were subjected to UV light and response time measurements carried out both before and after UV irradiation. After UV irradiation, the response time measurements showed increased response speeds. Further more, to check the stability of the system the test panel was heated to 60° C. for 1 hour and the response time measurement was repeated once again. As can be followed from FIG. 10, the response speed results remained same before and after heating, both being relatively faster than before UV irradiation. This experiment shows the effectiveness of having UV dimerizable side chains on a polymer.

The voltage holding ratio (VHR) measurements carried out at 50° C., using TOYO LCM2 LC characterization equipment showed 96% VHR for the negative type LC material both in commercial test panels and in the test display panels prepared using polymer A. This shows that the PI material synthesized (polymer A) do not have any negative effect on the VHR of the LC mixtures.

The on and off-state transmission measurements using a polarized microscope showed that polymer A has better on and off transmittance in comparison to the commercial PI material. Test panel with polymer A showed 6.2% off and 44% on transmittance, whereas, at the same voltage, commercial panel with commercial polyimide (SE-4811(0526) from Nissan Chemical, Industries Ltd.) remained with 7.2% off and 38.7% on transmittance values. FIG. 11 shows the polarized microscope pictures of on and off state of LC in the test panel with polymer A.

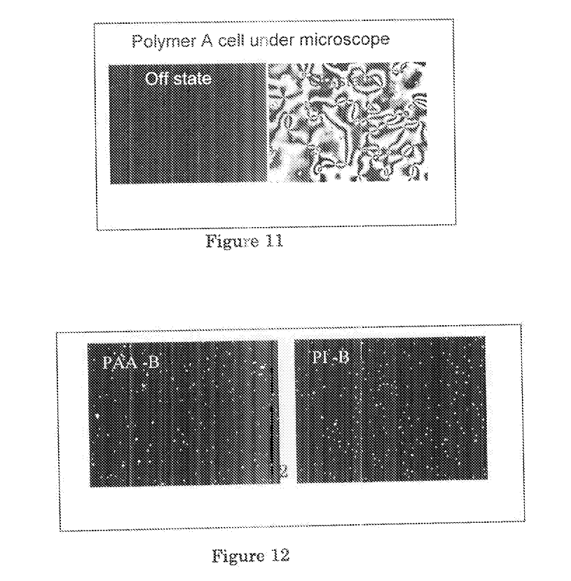

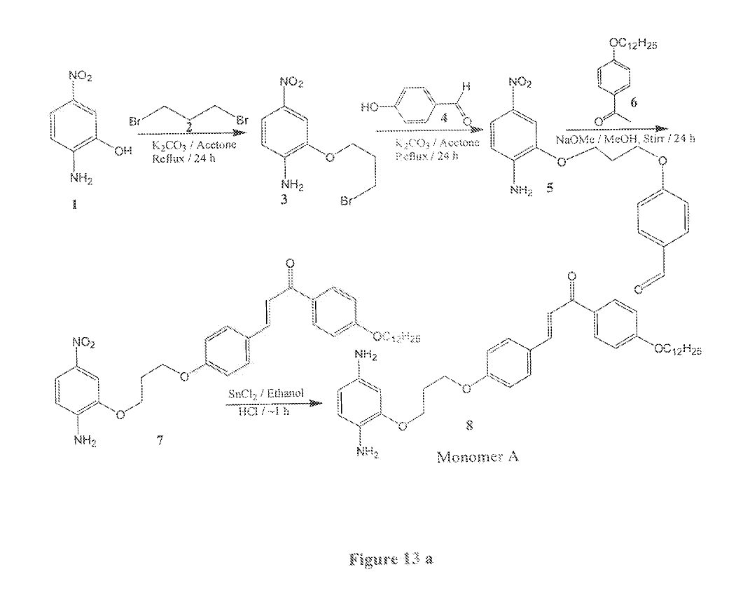

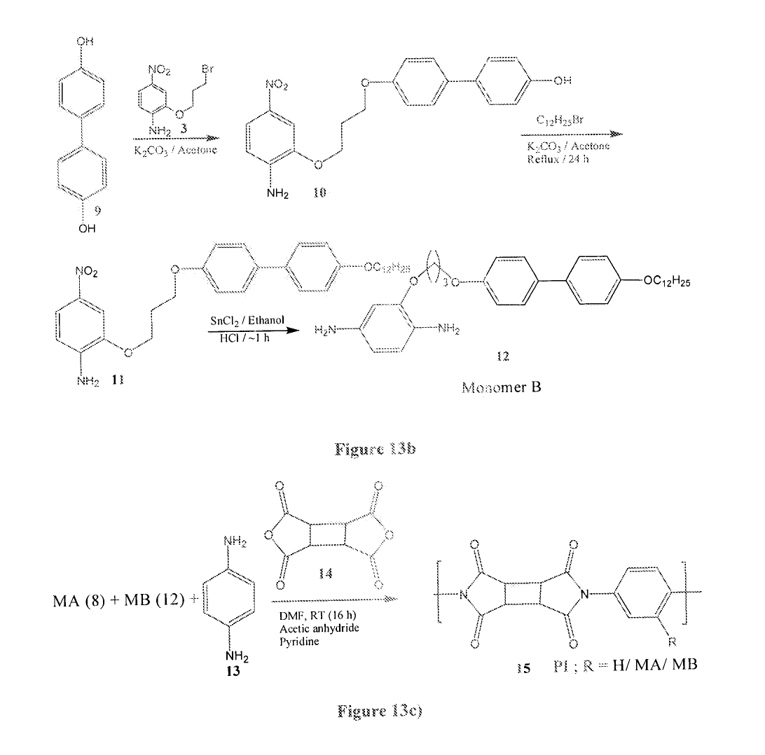

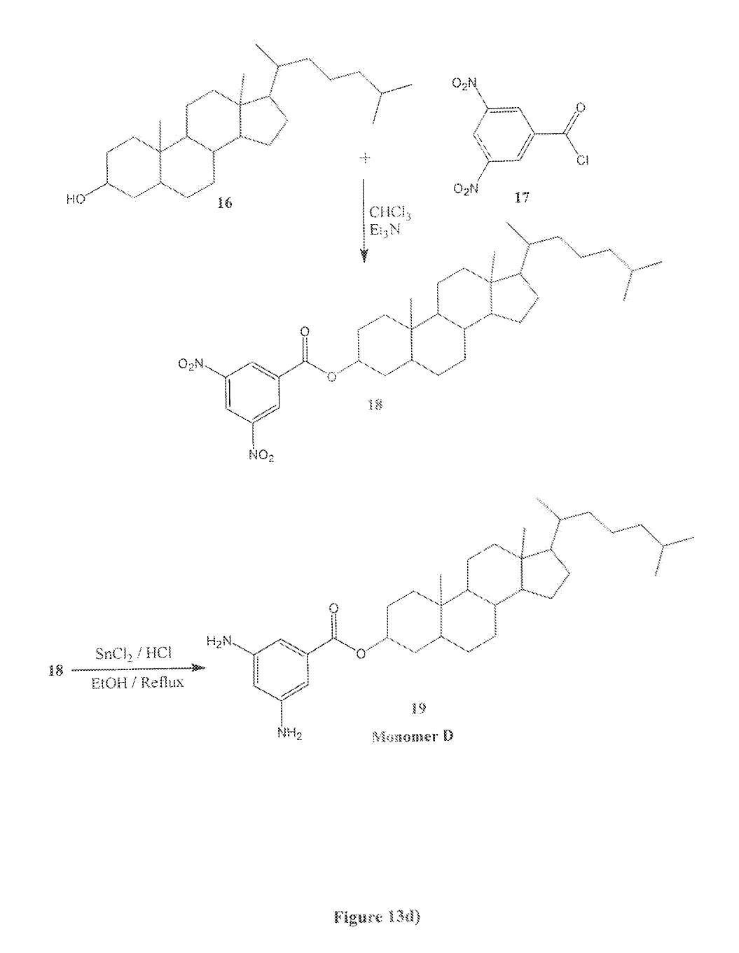

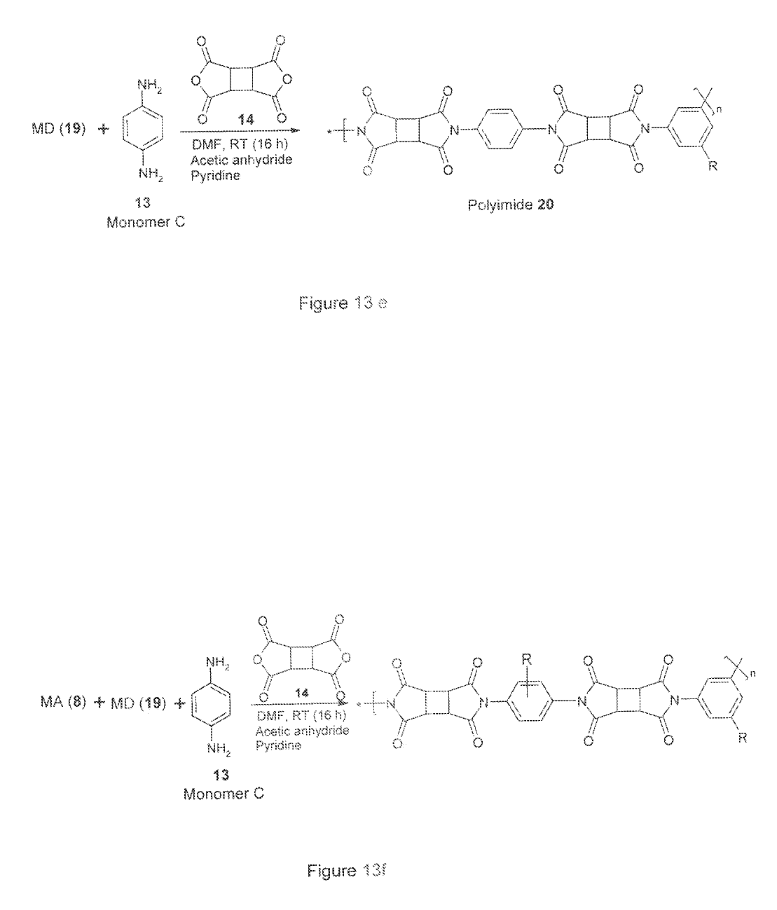

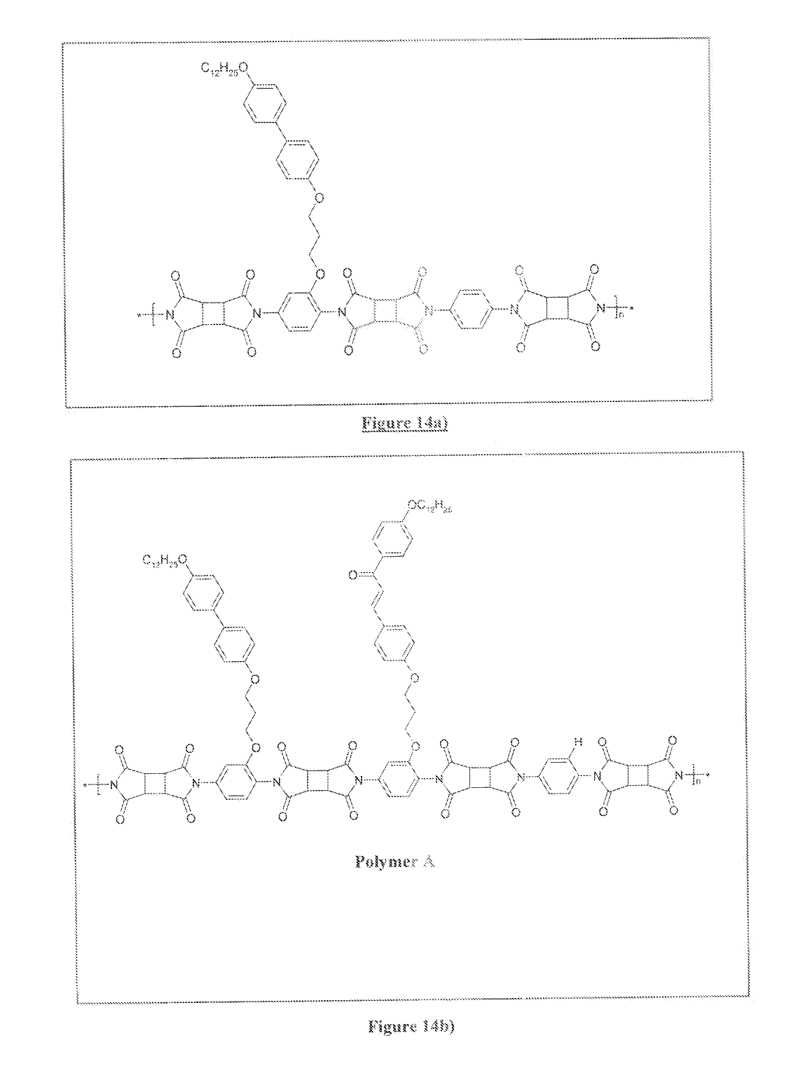

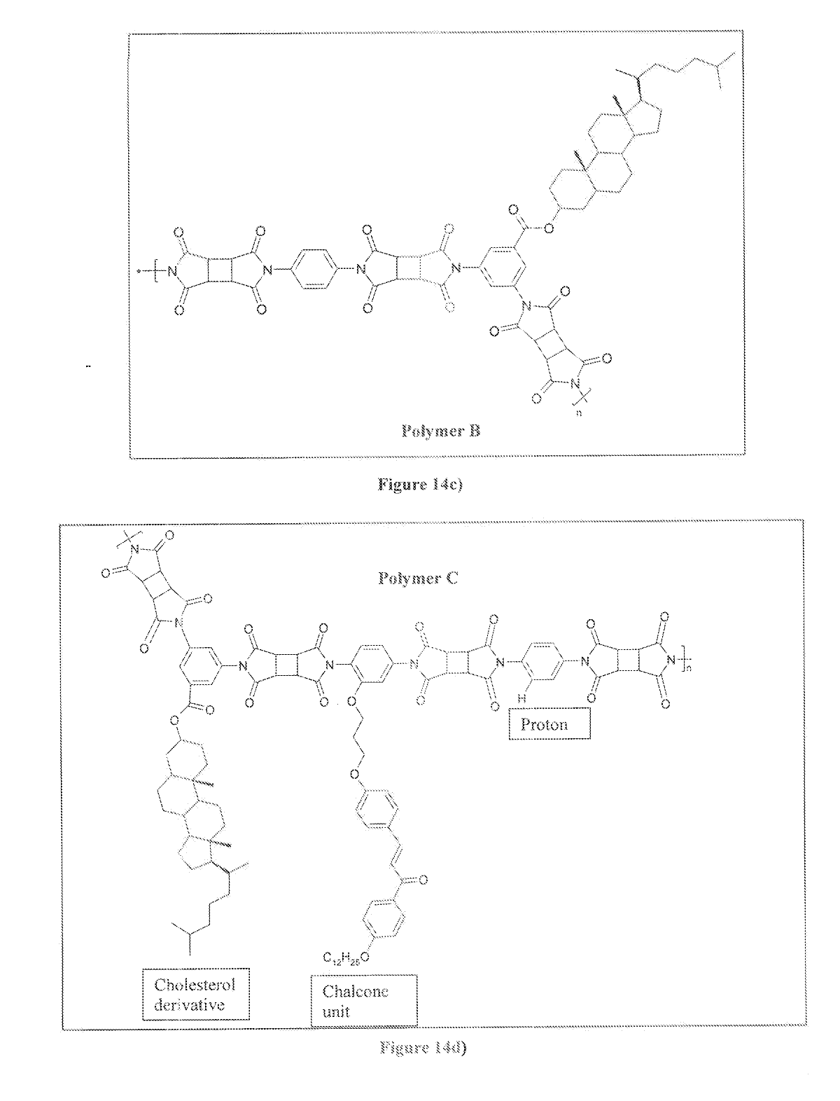

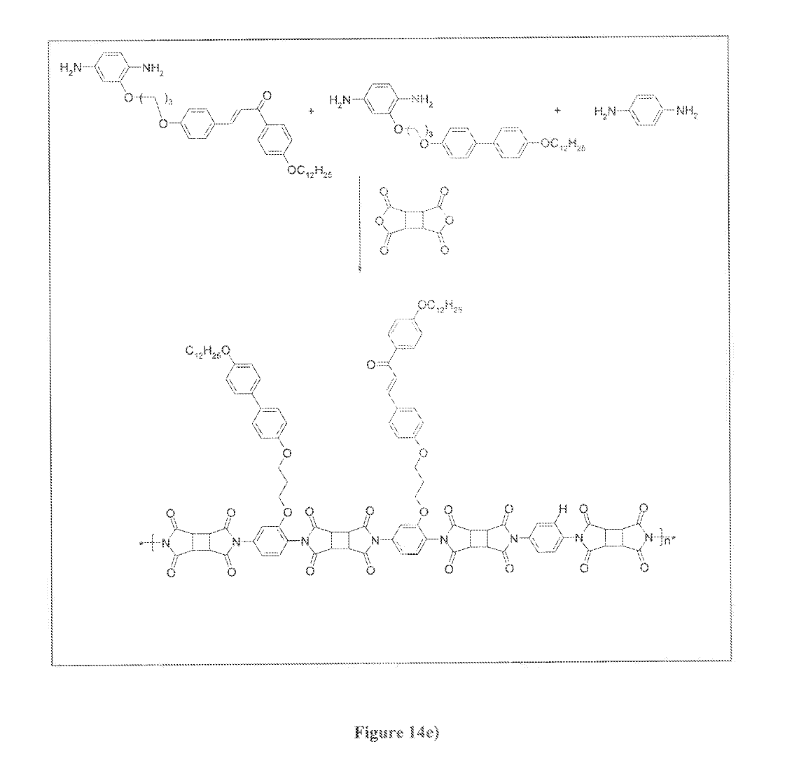

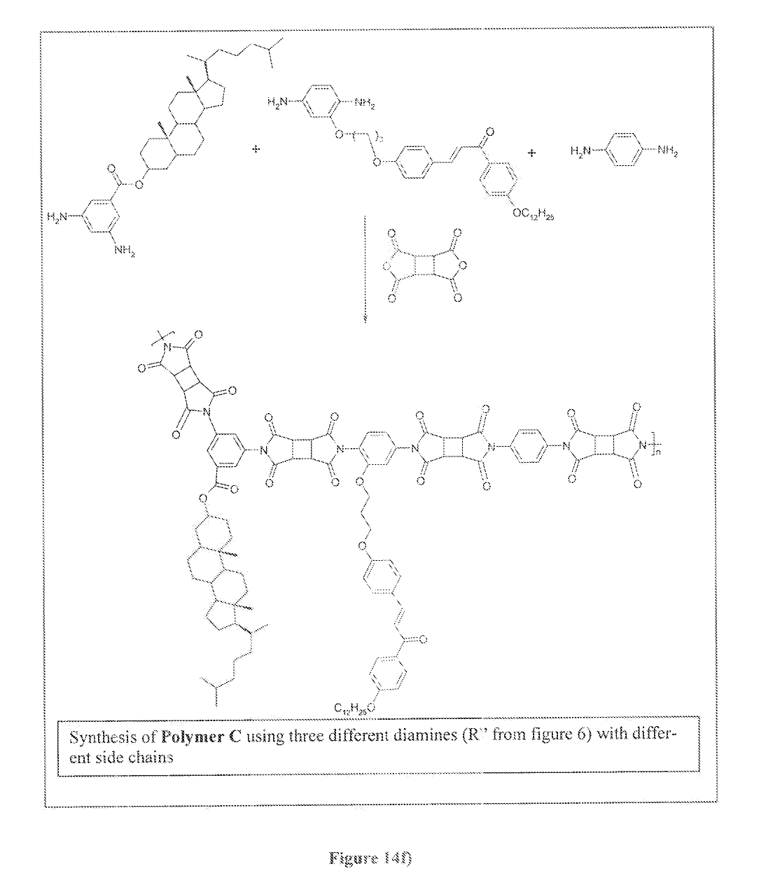

Very similar results could be obtained using polymer B as well. FIG. 12 shows the polarized microscope pictures of vertical alignment using polyamic acid B (PAA-B) and polymer B (PI-B). The white dots seen on the pictures are spacer beads.

The polyimides and polyamic acids in accordance with the present invention combine different structural units in a single polymer together. The polyimides in accordance with the present invention incorporate sidechains which promote a vertical alignment. Moreover, they incorporate photoreactive sidechains which also promote vertical alignment but additionally can be UV-exposed to provide for a pre-tilt to the liquid crystal materials. This, in turn, provides for better characteristics in liquid crystal displays, in terms of voltage holding ratios, contrast ratios, response times and on-state-transmittance and of-state-transmittance.

The features of the present invention disclosed in the specification, the claims and/or in the accompanying drawings, may, both separately and in any combination thereof, be material for realizing the invention in various forms thereof.

1. A polyamic acid obtained by reacting a dianhydride, a first type of diamine and a second type of diamine, wherein said first type of diamine has a sidechain that is UV light dimerizable, said sidechain being selected from the group consisting of 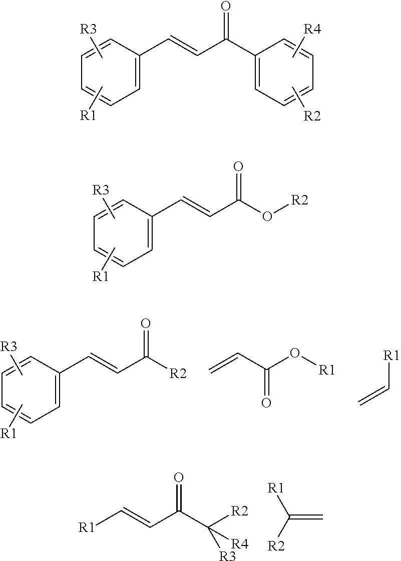
wherein
(i) R1-R4 are each independently selected from the group consisting of 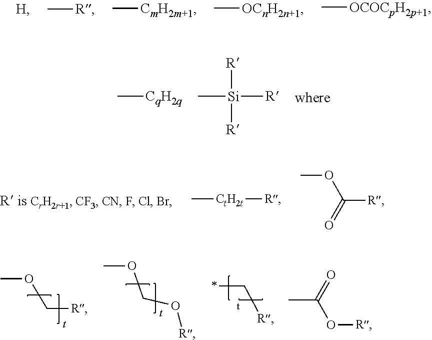
with the proviso that one of R1 to R4 is one of the aforementioned structures having R″, R″ denoting attachment of said sidechain to said diamine,
or wherein
(ii) R1 to R4 are each independently selected from the group consisting of 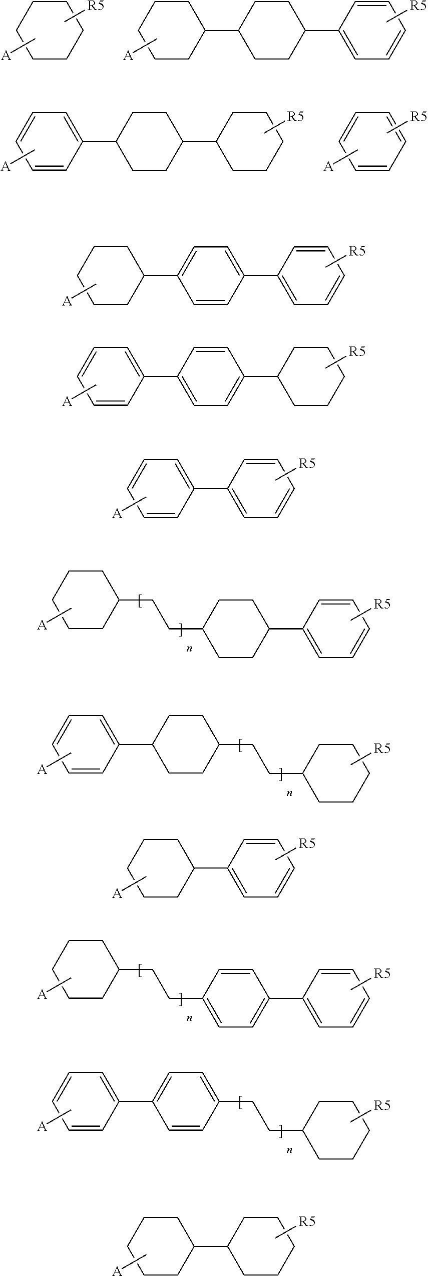 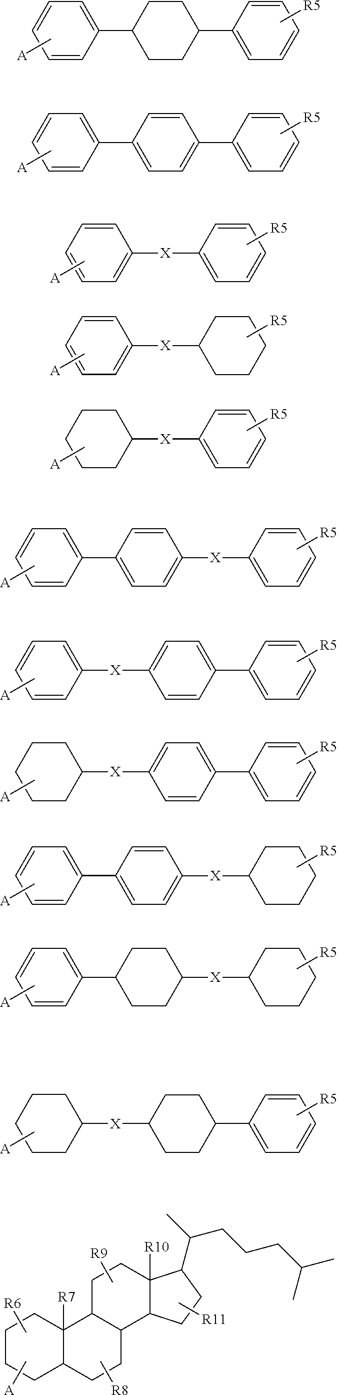 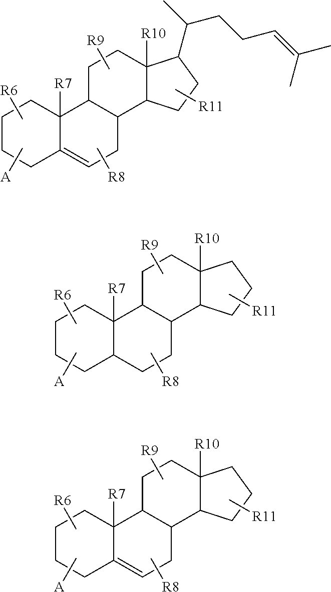
“A” representing the point of attachment at R1-R4; X being alkyl, ether, ester, cycloalkane, O, S, or NH; and wherein R5-R11 at each occurrence, are independently selected from the group consisting of 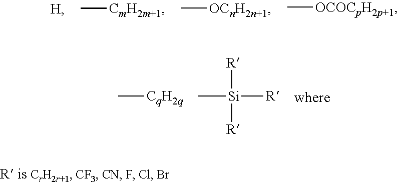
with the proviso that one of R1 to R4 is one of the aforementioned structures having R″, R″ denoting attachment of said sidechain to said diamine,
and wherein said second type of diamine has a sidechain that promotes vertical alignment of a liquid crystal material, when in contact with said sidechain, said sidechain being selected from the group consisting of 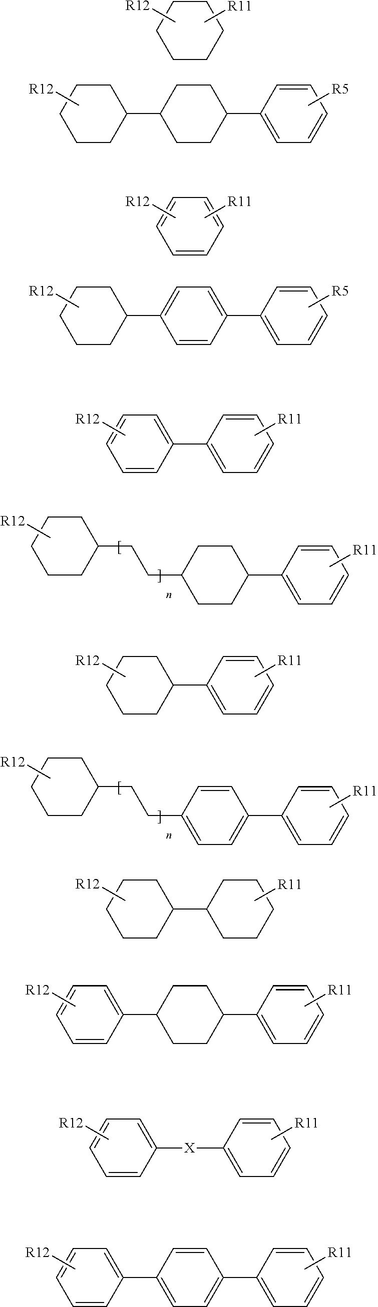 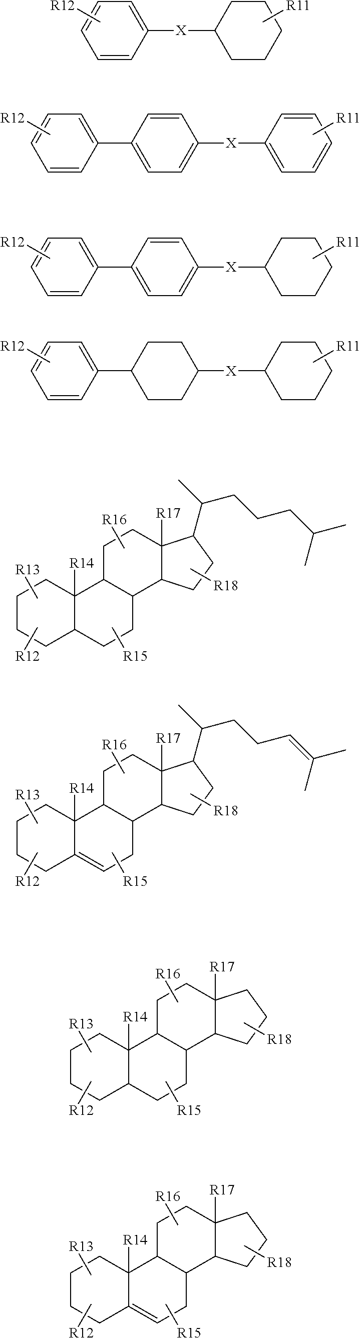
X being alkyl, ether, ester, cycloalkane, O, S, or NH; and wherein
(iii) R11-R18 are each independently selected from the group consisting of 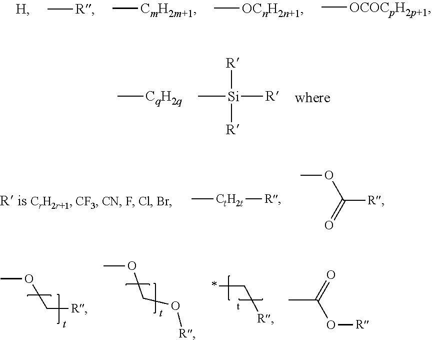
with the proviso that one of R11 to R12, is one of the aforementioned structures having R″,
R″ denoting attachment of said sidechain to said diamine,
or wherein
(iv) R11 to R18 are each independently selected from the group consisting of 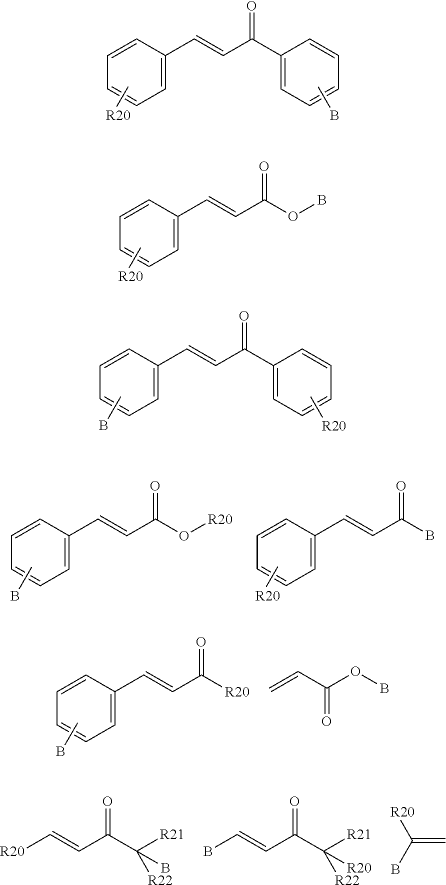
“B representing the point of attachment at R11-R18; and wherein R20-R22 are each independently selected from the group consisting of 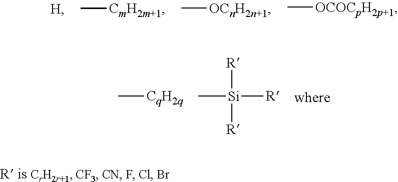
with the proviso that one of R11 to R12 is one of the aforementioned structures having R″, R″ denoting attachment of said sidechain to said diamine;
and wherein, in said polyamic acid, m, n, p, q, r, t are each independently selected from 0 to 20, preferably 0 to 10, and
with the proviso that said polyamic acid has been obtained by reacting said at least one type of diamine having a UV light dimerizable sidechain and said at least one type of diamine having a sidechain that promotes vertical alignment with said dianhydride.

2. The polyamic acid according to claim 1, wherein said dianhydride is selected from the group consisting of 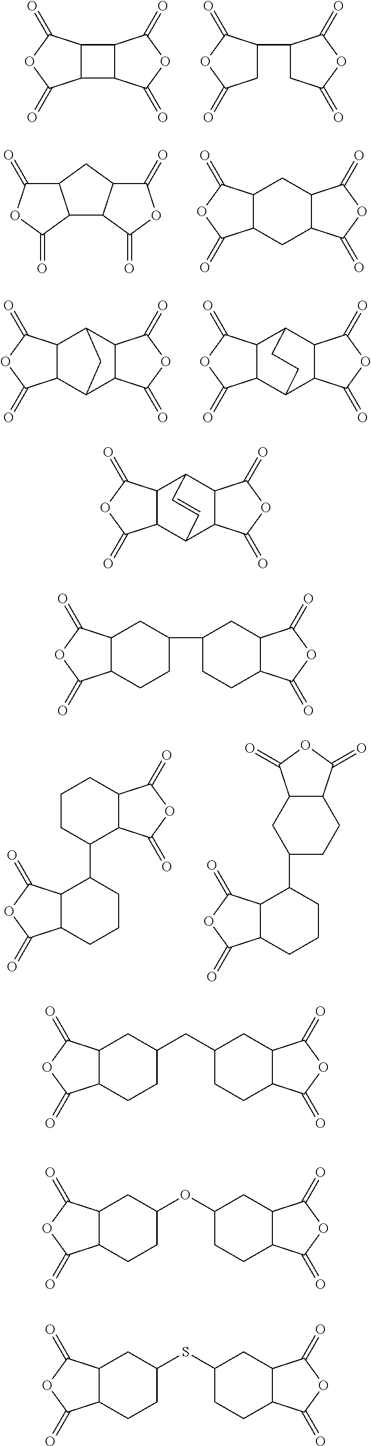 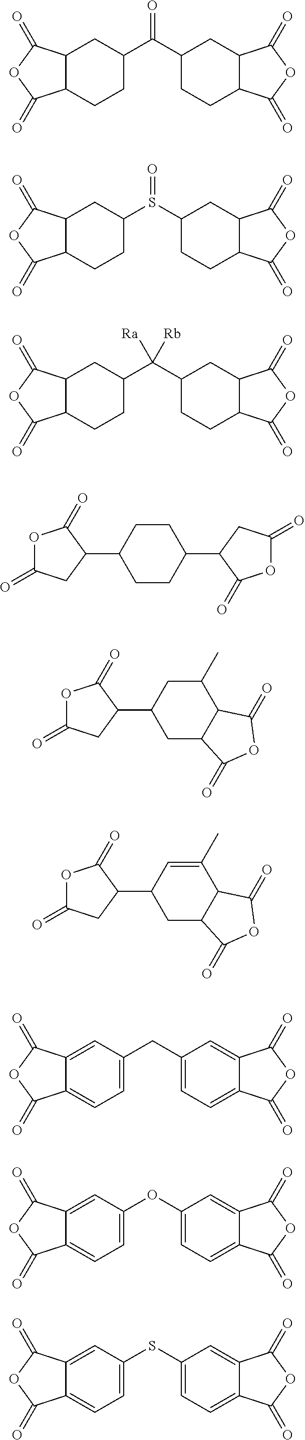 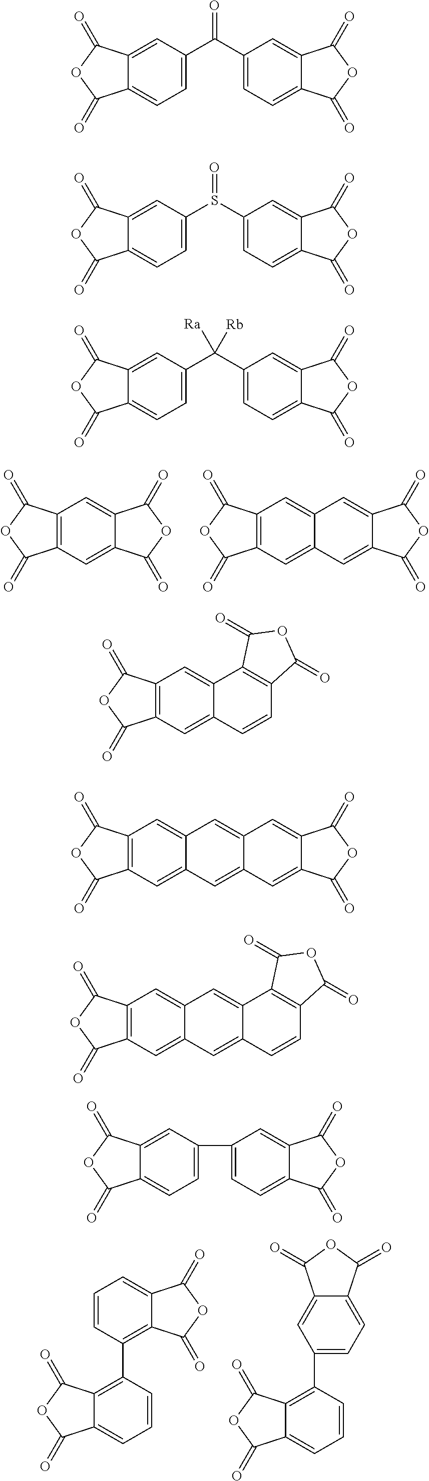 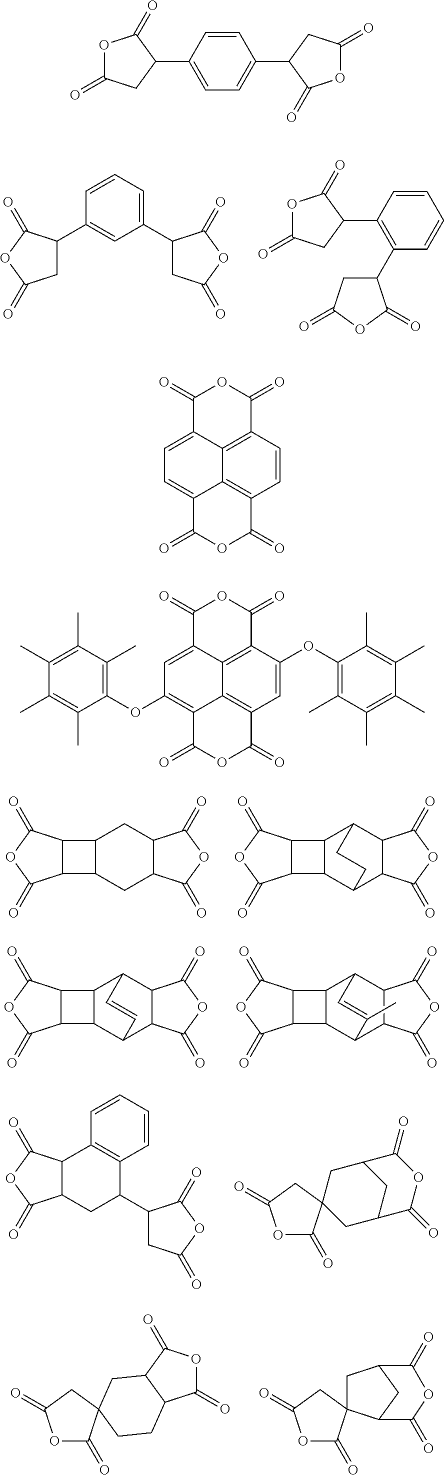
Ra and Rb each independently selected from the group consisting of alkyl, CF₃, F, Cl, Br, and CN.

3. The polyamic acid according to claim 1, wherein the diamine is selected from the group consisting of 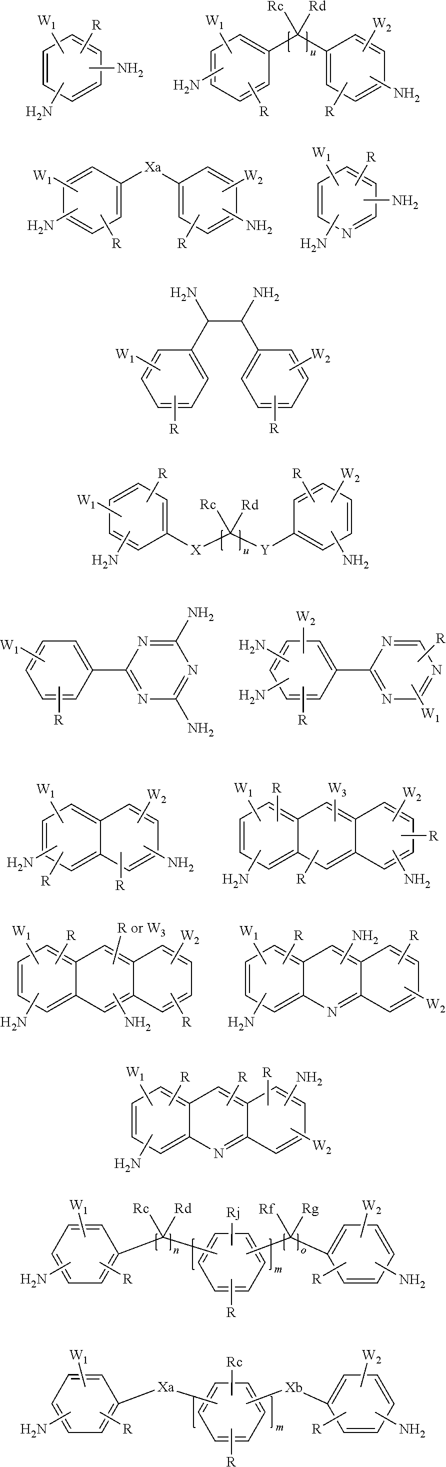 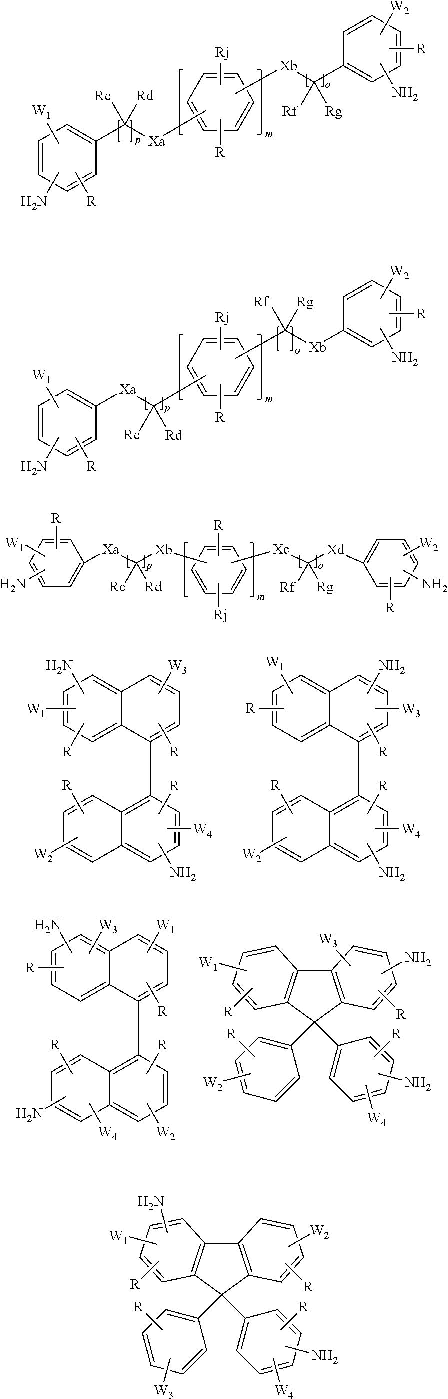 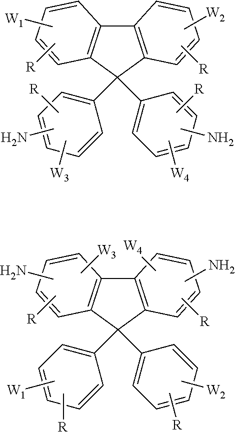
wherein
Rc, Rd, Rf, Rg, Rj are independently, at each occurrence, selected from; H, F, Br, Cl, CF₃, CN, CₙH_{2+‘}, OH, COORₑ where Rₑ=H or CₙH₂ₙ₊₁
Xa, Xb, Xc, Xd are independently, at each occurrence, selected from; CₙH₂ₙ, S, SO₂, N(Rₕ)₂ (Rₕ=H or CₙH₂ₙ₊₁), O, COO, CO
W₁ to W₄ are independently, at each occurrence, selected from; H, OH, CₙH₂ₙ₊₁, CF₃, Cl, Br, I, F, CN, COORₖ where Rₖ=H₂ₙ₊₁
n, m, o, p are independently, at each occurrence, selected from; 0 to 20
wherein R represents a sidechain as defined in claim 1.

4. The polyamic acid according to claim 3, obtained by additionally reacting said dianhydride with a third type of diamine, said diamine being as defined in claim 3, but having no sidechain, but instead having R═H.

5. A polyimide obtained by
(a) reacting the polyamic acid according to claim 1 with acetic anhydride, or
(b) exposing said polyamic acid to a temperature >100° C. for a period in the range of from 1 min to 24 h.

6. The polyimide according to claim 5, selected from the group consisting of 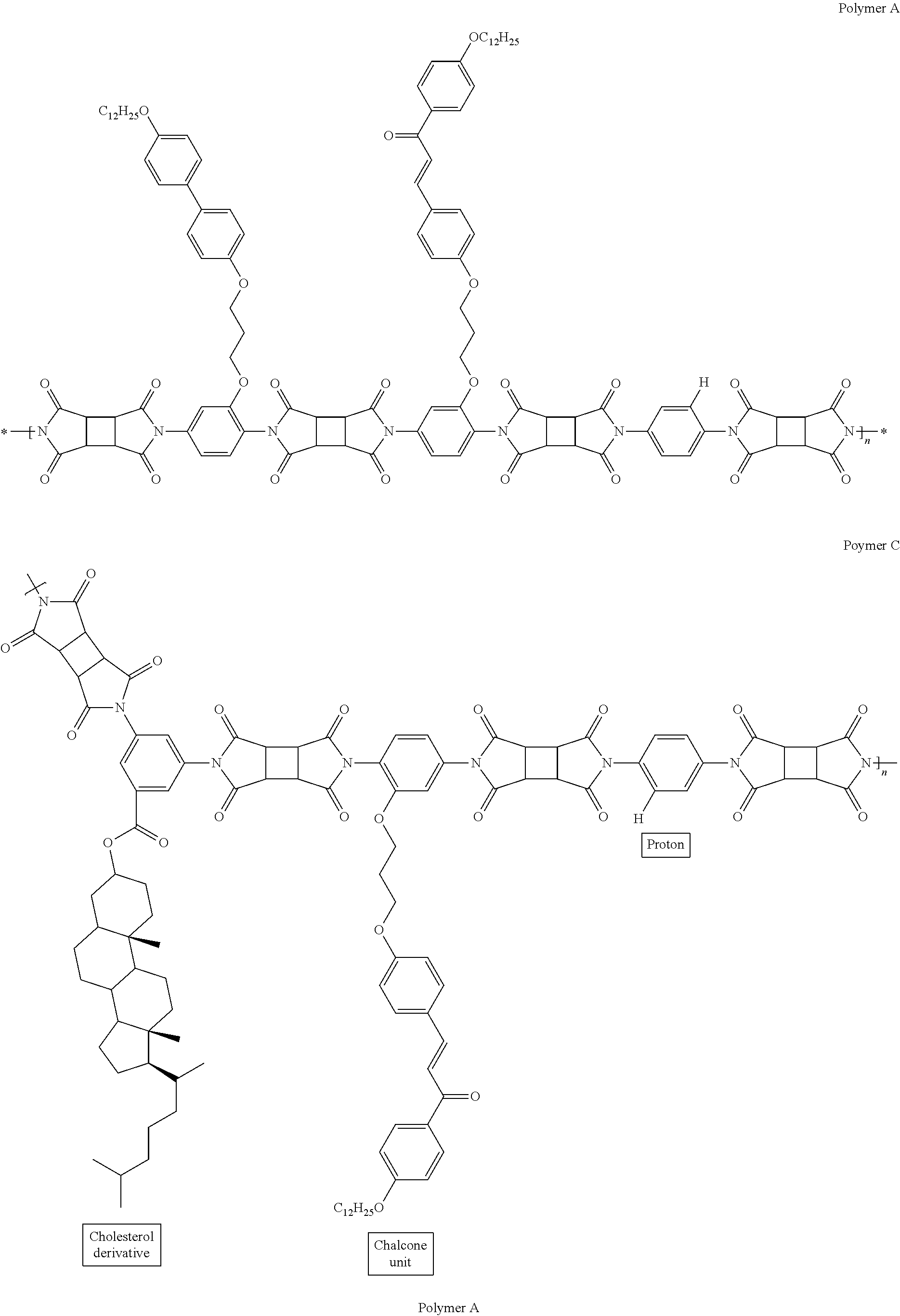
n being chosen such that the molecular weight of the polymer is in the range of from 20000 to 450000,
with the proviso that the arrangement of sidechains relative to each other within said polyimide is not limited to the one shown above.

7. The polyimide according to claim 5, wherein after reacting said dianhydride and said diamines and after converting the resultant polyamic acid to a polyimide, the resultant polyimide is exposed to UV-radiation.

8. A substrate having a film of the polyimide according to claim 5 deposited thereon, said film having a thickness in the range of from 50 nm to 2 μm.

9. A liquid crystal display comprising an alignment layer for alignment of liquid crystal material within said liquid crystal display, said alignment layer being a film of polyimide, said polyimide being as defined in claim 5.

10. The liquid crystal display according to claim 9, said film having a thickness in the range of from 50 nm to 2 μm.

11. The liquid crystal display according to claim 9, having response times of <40 ms at an applied voltage of 2.5 V, and <20 ms at an applied voltage of from 3 V to 7.5 V, respectively, and/or a voltage holding ratio of >95%.

12. A method for reducing the response times of a liquid crystal display and/or for improving the on-state- and off-state-transmission and/or the voltage holding ratio of a liquid crystal display, said method comprising incorporating said polyimide according to claim 5 as an alignment layer of said polyimide in said liquid crystal display.

13. A method of producing a liquid crystal display comprising:
depositing a film of the polyimide according to claim 5 on a substrate,
contacting said film with a layer of liquid crystal material by applying said liquid crystal material to said film,
providing a further substrate of said liquid crystal display and applying a further film of said polyimide according to claim 5 thereon, and
contacting said layer of liquid crystal material with said further film of polyimide by applying said further substrate on said layer of liquid crystal material, thereby sandwiching the liquid crystal material between the two substrates.

14. A substrate having a film of the polyimide according to claim 5 deposited thereon, said film having a thickness in the range of from 50 nm to 1 μm.

15. A substrate having a film of the polyimide according to claim 5 deposited thereon, said film having a thickness in the range of from 50 nm to 500 nm.

16. The polyimide according to claim 6, which is polymer A.

17. The polyimide according to claim 6, which is polymer C.

18. The liquid crystal display according to claim 9, said film having a thickness in the range of from 50 nm to 1 μm.

19. The liquid crystal display according to claim 9, said film having a thickness in the range of from 50 nm to 500 nm.
